(19) United States
(12) Patent Application Publication
(10) Pub. No.: US 2026/0334184 A1
(43) Pub. Date: Oct. 22, 2026

(54) METHODS FOR MAKING SEMICONDUCTOR DEVICES HAVING AN OXIDE LINER FOR METAL INTERCONNECT

(71) Applicant: Tokyo Electron Limited, Tokyo (JP)

(72) Inventors: Jack Rogers, Nirasaki City (JP); Corey Lemley, Delmar, NY (US)

(21) Appl. No.: 19/184,228

(22) Filed: Apr. 21, 2025

(51) Int. Cl. H01L 21/768

(52) U.S. Cl. CPC H10W 20/076; H10W 20/056; H10W 20/062; H10W 20/081; H10W 20/092

(57) ABSTRACT

A method for making a semiconductor device can include providing an intermediate structure in a plasma chamber that includes a low-k dielectric layer, etching the dielectric layer to form a hole therein in the plasma chamber, forming an oxide liner on sidewalls of the hole using at least one direct current superposition process in the plasma chamber, such that at least part of a bottom of the hole is not covered by the oxide liner, where the oxide liner includes an oxide material that differs from the low-k dielectric material of the dielectric layer, and filling the hole with a metal, such as ruthenium, such that the metal is on the oxide liner and such that the oxide liner is between the metal and the dielectric layer at least at the sidewalls of the hole.

### TECHNICAL FIELD

The present disclosure relates generally to methods for manufacturing semiconductor devices, and more particularly, providing an oxide liner for a metal interconnect in a method for manufacturing semiconductor devices.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other. The manufacturing stage and device portion for such intermetal and interlayer dielectric layers, or interconnects, is typically referred to as back-end-of-the-line (BEOL).

Normally, each metal layer must form an electrical contact to at least one additional metal layer. Such electrical contact can be achieved by etching a feature (i.e., a via) in the interlayer dielectric layer that separates the metal layers, and filling the resulting via with a metal to create an interconnect. A “via” sometimes refers to any feature such as a hole, line, or other similar feature formed within a dielectric layer and filled with a metal structure that provides an electrical connection or metal interconnect through the dielectric layer to another conductive structure underlying the dielectric layer. Similarly, metal structures connecting two or more vias are sometimes referred to as “trenches” or metal lines or interconnect lines.

As new materials are introduced to improve and progress semiconductor manufacturing for BEOL, new problems arise with the use of such new materials. One such problem is the adhesion strength between materials being too weak to withstand the forces exerted on the wafer during chemical mechanical polishing (CMP), which can cause metal plugs or new formed metal features to be extracted or removed from a corresponding via or trench. Such unspecified removal is typically undesirable because it can reduce yield and increase manufacturing costs and waste. Thus, there is a need to address and solve such problems with new BEOL process flows.

### SUMMARY

In an embodiment of the present disclosure, a method for making a semiconductor device can include: providing a first intermediate structure in a first plasma chamber, where the first intermediate structure includes a first dielectric layer, where the first dielectric layer includes a low-k dielectric material having a first dielectric constant less than 3.9; etching the first dielectric layer to form a first hole therein in the first plasma chamber; forming a first oxide liner on sidewalls of the first hole using at least one direct current superposition process in the first plasma chamber, such that at least part of a bottom of the first hole is not covered by the first oxide liner, where the first oxide liner includes an oxide material that differs from the low-k dielectric material of the first dielectric layer; and filling the first hole with a metal such that the metal is on the first oxide liner and such that the first oxide liner is between the metal and the first dielectric layer at least at the sidewalls of the first hole.

In an embodiment of the present disclosure, a method for making a semiconductor device can include: providing a first intermediate structure in a first plasma chamber, where the first intermediate structure includes a first dielectric layer, where the first dielectric layer includes a low-k dielectric material having a first dielectric constant less than 3.9, where the first intermediate structure further includes an underlying conductive structure below the first dielectric layer; etching the first dielectric layer to form a first hole therein using a first set of plasma chamber parameters in the first plasma chamber, where the etching of the first dielectric layer to form the first hole opens to the underlying conductive structure and exposes an underlying-conductive-structure top surface of the underlying conductive structure; depositing a first oxide liner over the first intermediate structure and on sidewalls of the first hole in the first plasma chamber using a first direct current superposition process with a second set of plasma chamber parameters, where the second set of plasma chamber parameters differs from the first set of plasma chamber parameters; removing a hole-bottom portion of the first oxide liner at a bottom of the first hole using a third set of plasma chamber parameters in the first plasma chamber, such that at least part of the first oxide liner remains on at least part of the sidewalls of the first hole, where the third set of plasma chamber parameters differs from the first set of plasma chamber parameters and the second set of plasma chamber parameters, where the removing of the hole-bottom portion of the first oxide liner opens to the underlying conductive structure and exposes the underlying-conductive-structure top surface of the underlying conductive structure; and filling the first hole with a metal such that the metal is directly on the underlying-conductive-structure top surface of the underlying conductive structure at the bottom of the first hole, such that the metal is directly on the first oxide liner, and such that the first oxide liner is between the metal and the first dielectric layer at least at the sidewalls of the first hole.

In an embodiment of the present disclosure, a method for making a semiconductor device can include: providing a first intermediate structure in a first plasma chamber, where the first intermediate structure includes a first dielectric layer, where the first dielectric layer includes a low-k dielectric material including silicon and oxygen, where the low-k dielectric material has a first dielectric constant less than 3.9; etching the first dielectric layer to form a first hole therein using a first set of plasma chamber parameters in the first plasma chamber; depositing a first oxide liner over the first intermediate structure and directly on sidewalls of the first hole in the first plasma chamber using a direct current superposition process with a second set of plasma chamber parameters, where the first oxide liner includes a silicon dioxide material having a second dielectric constant of 3.9 or greater than 3.9, where the second set of plasma chamber parameters differs from the first set of plasma chamber parameters; removing a hole-bottom portion of the first oxide liner at a bottom of the first hole using a third set of plasma chamber parameters in the first plasma chamber, such that at least part of the first oxide liner remains on at least part of the sidewalls of the first hole, where the third set of plasma chamber parameters differs from the first set of plasma chamber parameters and the second set of plasma chamber parameters; and filling the first hole with ruthenium such that the ruthenium is directly on the first oxide liner and such that the first oxide liner is between the ruthenium and the first dielectric layer at least at the sidewalls of the first hole.

In an embodiment of the present disclosure, a semiconductor device can include: a first dielectric layer having a first hole therein, where the first dielectric layer includes a low-k dielectric material having a first dielectric constant less than 3.9; a first oxide liner directly on the first dielectric layer at a sidewall of the first hole, where the first oxide liner includes an oxide material having a second dielectric constant of 3.9 or greater than 3.9; and a ruthenium conductive structure directly on the first oxide liner in the first hole.

### BRIEF DESCRIPTION OF THE DRAWINGS

For a more complete understanding of the present disclosure, and advantages thereof, reference is now made to the following descriptions of example embodiments taken in conjunction with the accompanying drawings, in which:

FIGS. 1A to 1D are cross-section views illustrating intermediate structures of a semiconductor device having a ruthenium plug and illustrating a problem that can occur;

FIG. 2 is a schematic of a plasma processing system that can be used in an embodiment of the present disclosure;

FIGS. 3A to 3F are cross-section views illustrating intermediate structures of a semiconductor device made using a method according to an embodiment of the present disclosure;

FIGS. 4A to 4C are cross-section views illustrating intermediate structures of a semiconductor device made using a method according to an embodiment of the present disclosure;

FIGS. 5A to 5E are cross-section views illustrating intermediate structures of a semiconductor device made using a dual damascene method according to an embodiment of the present disclosure;

FIG. 6 is a perspective view of the oxide liner of FIG. 5C, according to an embodiment of the present disclosure;

FIGS. 7A to 7F are cross-section views illustrating intermediate structures of a semiconductor device made using a subtractive semi-damascene method according to an embodiment of the present disclosure;

FIG. 8 is a flow chart of a method of making a semiconductor device in accordance with an embodiment of the present disclosure;

FIG. 9 is a flow chart of a method of making a semiconductor device in accordance with an embodiment of the present disclosure;

FIG. 10 is a flow chart of a method of making a semiconductor device in accordance with an embodiment of the present disclosure; and

FIG. 11 is a flow chart of a method of making a semiconductor device in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure. A number of example embodiments of the present disclosure are described below. Other embodiments can also be understood from the entirety of the specification as well as the claims filed herein. It can be understood that various features of different embodiments can be combined.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scopes of rights according to the present disclosure.

In the present disclosure and drawings, labels such as “M0”, “M1”, and “M2” can be used to describe various interconnect levels in the drawings, which can be commonly referred to as “metallization levels” in the semiconductor industry. However, a labeling of interconnect levels in the drawings for describing a given example embodiment of the present disclosure may not correspond to the labels used to name or identify actual interconnect levels, or to define an actual vertical location thereof, in an actual implementation of an embodiment. Thus, such labels used in the present specification do not necessarily limit an interconnect level to an actual interconnect level that implements an embodiment of the present disclosure. For example, an interconnect level labeled “M1” in present specification may correspond to an actual interconnect level located at or designated as level M5 while still being in accordance with an embodiment of the present disclosure.

Recent research and development for BEOL processes are exploring the use of ruthenium for BEOL interconnects. One advantage of using ruthenium for relatively smaller vias is better conductivity compared with copper-based via structures. Another advantage of using ruthenium is that ruthenium does not require a barrier layer relative to dielectric materials of BEOL structures. However, research has shown that ruthenium has weaker adhesion to some commonly-used low-k dielectric materials (e.g., dielectric materials having a dielectric constant (k) less than 3.9) compared to silicon dioxide (e.g., dielectric materials having a dielectric constant (k) of 3.9 or more). During chemical-mechanical polishing (CMP), ruthenium formed directly on some commonly-used low-k dielectric materials has caused the ruthenium via plug and/or interconnect line to be dislodged or displaced (sometimes referred to a line wiggle).

Another issue with using ruthenium together with low-k dielectric materials in BEOL is that ruthenium is typically best etched with an oxide-based chemical. However, such oxide-based chemicals can greatly damage and/or change the electrical properties of some commonly-used low-k dielectric materials. For example, during a subtractive semi-damascene process flow for forming a ruthenium interconnect structure for BEOL, patterning and etching ruthenium using an oxide-based chemical can damage and/or change the electrical properties of some commonly-used low-k dielectric materials.

Through research and development, the inventors have developed BEOL process flows and structures, in accordance with embodiments of the present disclosure, that can solve the problems outlined above by using a silicon dioxide liner for a ruthenium interconnect structure for BEOL, for example. An embodiment of the present disclosure can improve the adhesion strength of a ruthenium interconnect structure relative to low-k dielectric material by incorporating an oxide liner (e.g., silicon dioxide). Using an embodiment of the present disclosure, an oxide liner (e.g., silicon dioxide) can protect an underlying low-k dielectric material and act as an etch stop layer or at least a shield layer for the underlying low-k dielectric material during the etching of ruthenium in a subtractive semi-damascene process flow for forming a ruthenium interconnect structure for BEOL, for example.

In some embodiments of the present disclosure, a method for forming a semiconductor device can include: providing a first intermediate structure in a first plasma chamber, where the first intermediate structure includes a first dielectric layer, the first dielectric layer including a low-k dielectric material having a first dielectric constant less than 3.9; etching the first dielectric layer to form a first hole therein using a first set of plasma-chamber parameters in the first plasma chamber; depositing/forming a first oxide liner over the first intermediate structure and on sidewalls of the first hole in the first plasma chamber using a direct current superposition process with a second set of plasma-chamber parameters, where the first oxide liner includes an oxide material (e.g., silicon dioxide) that differs from the low-k dielectric material of the first dielectric layer, where the second set of plasma-chamber parameters differs from the first set of plasma-chamber parameters; removing a hole-bottom portion of the first oxide liner at a bottom of the first hole using a third set of plasma-chamber parameters in the first plasma chamber, such that at least part of the first oxide liner remains on at least part of the sidewalls of the first hole, where the third set of plasma-chamber parameters differs from the first set of plasma-chamber parameters and the second set of plasma-chamber parameters; and filling the first hole with a metal (e.g., ruthenium) such that the metal is on the first oxide liner and such that the first oxide liner is between the metal and the first dielectric layer at least at the sidewalls of the first hole.

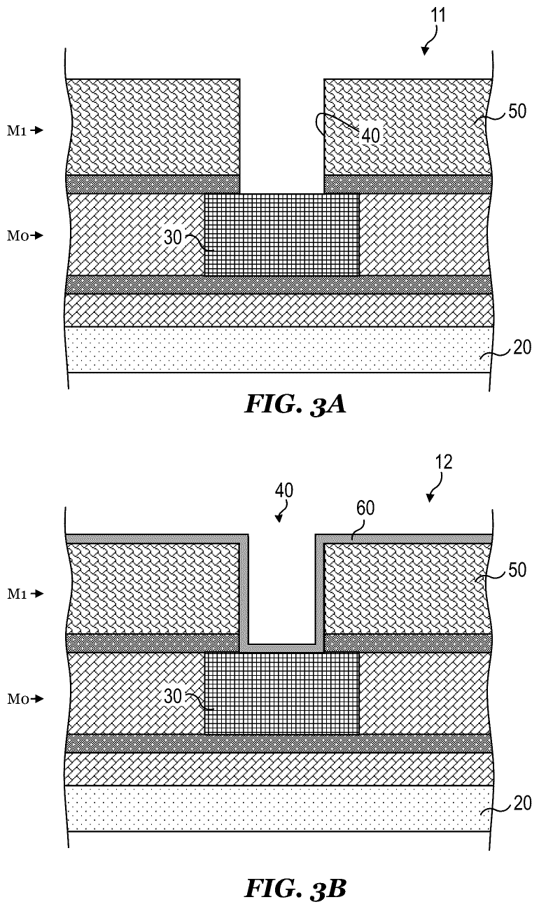

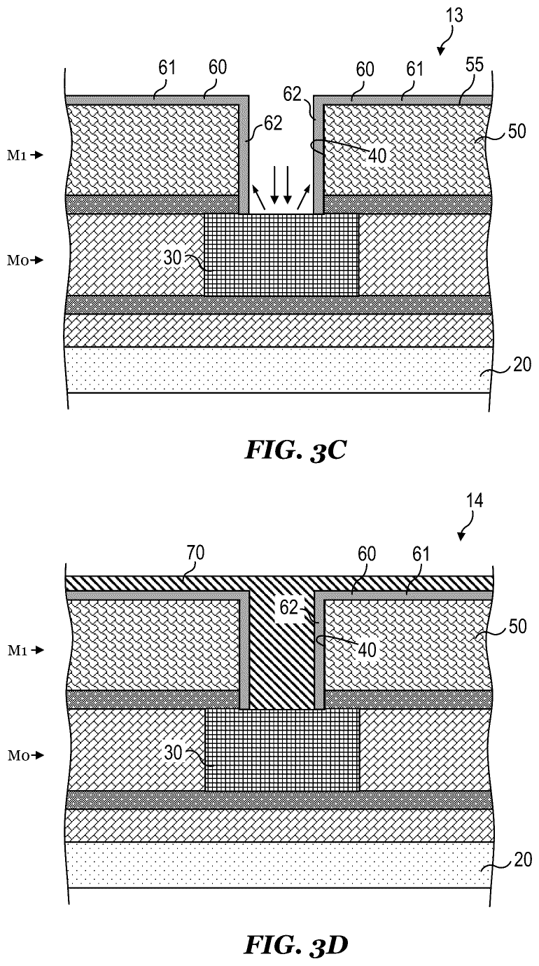

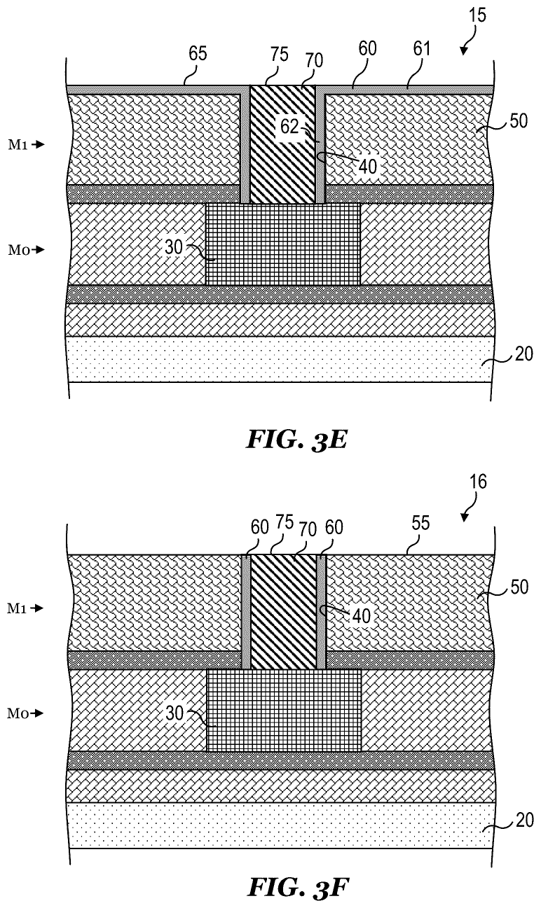

FIGS. 3A to 5E and 7A to 7F are various cross-section views illustrating various intermediate structures during various methods of making a semiconductor device according to some example embodiments of the present disclosure. For simplification and illustration purposes, FIGS. 3A to 5E and 7A to 7F are merely showing some portions of a semiconductor device as intermediate structures that can be relevant to a method of making the semiconductor device according to an example embodiment of the present disclosure. For example, in FIGS. 3A to 5E and 7A to 7F, to simplify the drawings, as can be readily understood by one of ordinary skill in the pertinent art, additional layers and structures of a semiconductor device made before, under, below, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), frontend-of-line (FEOL) stages or levels, transistors, diodes, capacitors, resistors, inductors, integrated circuits, memory cells, logic, processor portions, digital devices, analog devices, semiconductor wafer, silicon-on-insulator wafer, or combinations thereof, for example. Also in FIGS. 3A to 5E and 7A to 7F, to simplify the drawings, as can be readily understood by one of ordinary skill in the pertinent art, additional layers and structures of a substrate for a semiconductor device made after, over, above, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), passivation layers, contact pads, local interconnects, global interconnects, wire bonding, packaging, or combinations thereof, for example.

In an actual completed semiconductor device cross-section, the intermediate structures, which are illustrated and represented in the drawings of the present disclosure in a simplified manner as having squared edges and/or linear shapes, can be actually more rounded, have rounded corners, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on the scale of atoms to 5 nanometers in size), or may be removed during processing and little or no remnants of certain layers, features, or portions in the final semiconductor device publicly sold and used.

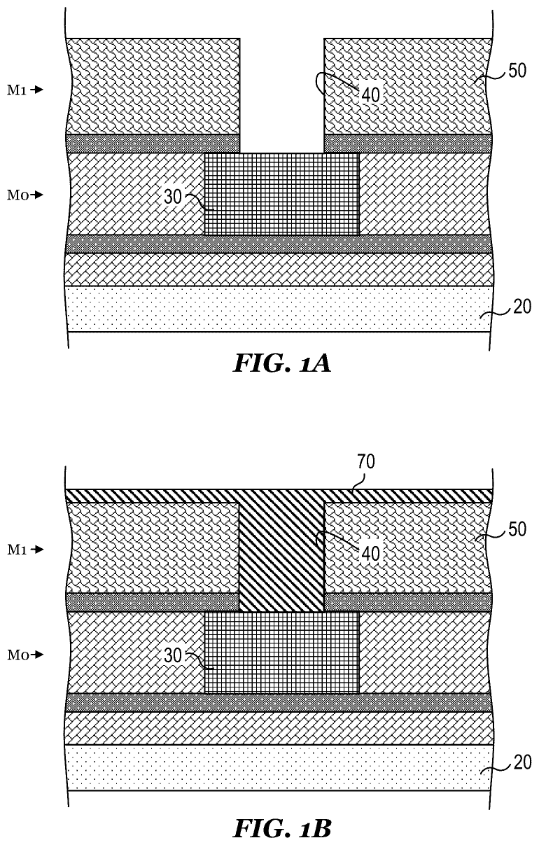

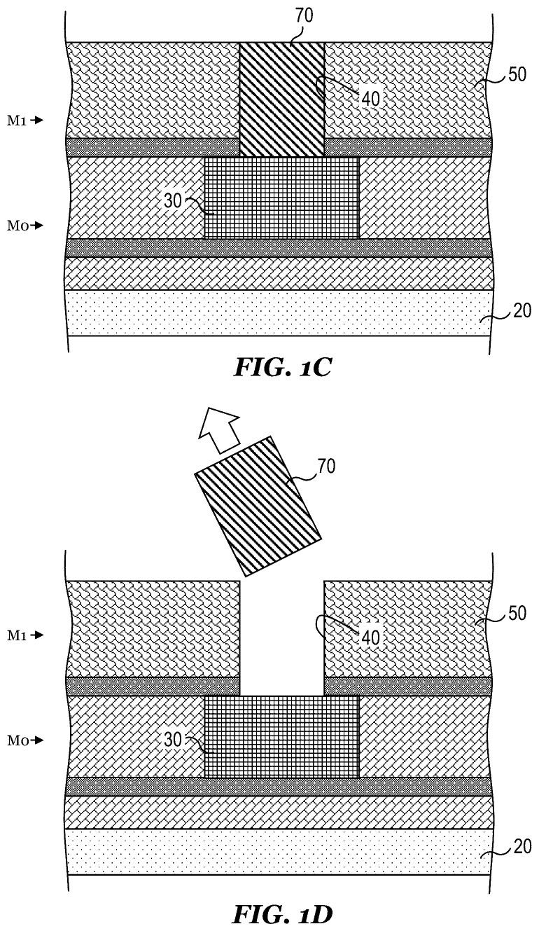

FIGS. 1A to 1D are cross-section views illustrating intermediate structures of a semiconductor device having a ruthenium plug and illustrating a problem that can occur. Referring to FIG. 1A, a first intermediate structure can include multiple levels/layers of insulating layers on a substrate 20. The intermediate structure can include a first dielectric layer 50 made of a low-k dielectric material (i.e., having a first dielectric constant less than 3.9). The first dielectric layer 50 can include a via hole 40 formed therein at interconnect level M1 and an underlying conductive structure 30 at interconnect level M0.

Referring to FIG. 1B, ruthenium 70 can fill the via hole 40 and overfill the via hole 40 such that an overburden of ruthenium 70 is on a top surface of the first dielectric layer 50. Unlike copper, ruthenium can be formed directly on the low-k dielectric material of the first dielectric layer 50.

Referring to FIGS. 1C and 1D, a chemical mechanical polishing (CMP) can be performed to remove the overburden of the ruthenium. However, as illustrated in FIG. 1D, research has shown that a CMP on such structure can result in the ruthenium 70 being dislodged from the via hole 40 due to a relatively weak adhesion strength between ruthenium and many typically-used low-k dielectric materials. Also, for conductive lines in trenches made from ruthenium deposited directly on some typical low-k dielectric materials, research has shown that “line wiggle” can occur, that is, lines being partially dislodged, delaminated, and/or damaging a sidewall of a trench allowing some ruthenium lines to be misaligned, tilted, displaced, delaminated, and moved from the locations for which the lines are intended to be located. Such line wiggle can provide unacceptable alignment and stability of interconnect lines, which typically have very small alignment tolerances for subsequently formed interconnect structures intended to electrically connect therewith. Such line wiggle can cause voids and open circuit portions of an interconnect structure, which can greatly reduce yield and reduce device reliability.

Research and development by the inventors showed that ruthenium was not having via plug dislodging and line wiggle issues during CMP with non-low-k dielectric material, such as silicon dioxide, for example. An embodiment of the present disclosure can resolve issues with via plug dislodging and line wiggle by implementing an oxide liner, such as silicon dioxide, between a ruthenium conductive structure and a low-k dielectric material, as will be described in more detail below for some example embodiments of the present disclosure.

Research and development by the inventors have resulted in various method embodiments for incorporating an oxide liner (e.g., as an adhesion layer/liner) on at least sidewalls of a hole so that ruthenium (or another metal having similar issues) can have a stronger adhesion with the oxide liner and the oxide liner can also adhere well with a given low-k dielectric material in an intermetal dielectric layer for BEOL. Research and development by the inventors have resulted in efficient and cost-effective method embodiments in which such oxide liner can be formed in a same plasma chamber as that used for etching the holes in the low-k dielectric material for a given intermetal dielectric layer for BEOL. Thus, a wafer does not necessarily need to be moved out of a given plasma chamber to form a suitable oxide liner in accordance with an embodiment of the present disclosure, which can result in manufacturing simplification, cost savings, and process flow efficiency, for example. A method embodiment of the present disclosure can make use of at least one direct current superposition (DCS) operation in a plasma system for forming an oxide liner for a metal interconnect structure. Next, an example plasma system that can be used in implementing an embodiment of the present disclosure will be described.

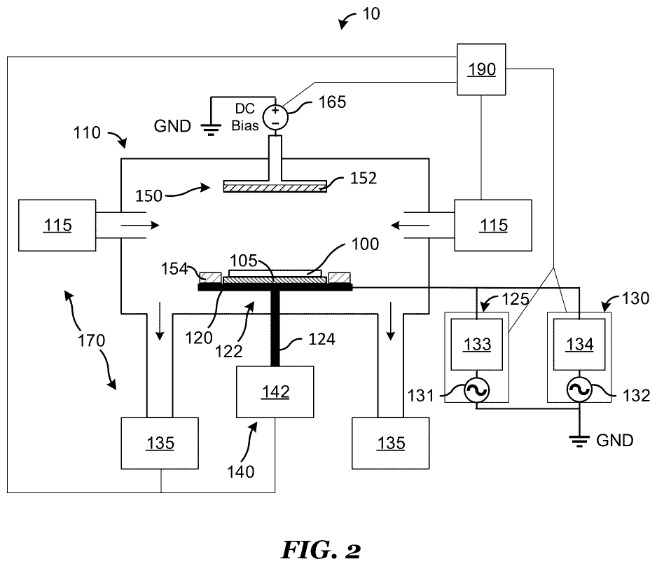

FIG. 2 illustrates a schematic of a plasma system 10 configured to perform plasma etching and deposition processes that can be suitable for use in an embodiment of the present disclosure. Referring to FIG. 2, a plasma system 10 can include a plasma chamber 110 in a capacitive coupled plasma (CCP) configuration. As explained in further detail below, the plasma chamber 110 can be equipped to execute plasma processes utilizing a direct current superposition (DCS) function.

A wafer holder 105 can be located in the plasma chamber 110. The wafer holder 105 can be configured to hold a wafer 100 having a major surface facing the inside of the plasma chamber 110. The wafer holder 105 can be a part of a pedestal 122 located in a bottom portion of the plasma chamber 110. The pedestal 122 can be also the wafer holder 105. The pedestal 122 can be connected to a support column 124 that extends out of the plasma chamber 110. Electrical wires, gas flow lines, and coolant pipes can be passing through the support column 124 to couple parts of the pedestal 122 to various other components of the plasma system 10 located outside the plasma chamber 110. The wafer holder 105 can be an electrostatic chuck (ESC) including ESC electrodes proximate below the surface of the wafer holder 105 on which the wafer 100 can be held. A top portion of the wafer holder 105 can include an insulator. The insulator can have a conductive coating.

Still referring to FIG. 2, the plasma system 10 can include a temperature control system 140 configured to maintain a backside of the wafer 100 at a controlled temperature. Parts of the temperature control system 140 can be used for sensing and adjusting the temperature and can be included in the pedestal 122. For example, the pedestal 122 can include a temperature sensor, such as a thermocouple or a thermistor configured to sense the temperature of the wafer 100. The pedestal 122 can have liquid coolant channels and resistive heating elements located below the surface of the wafer holder 105. A pipe for carrying cooling gas to grooves in the surface of the wafer holder 105 that contacts the backside of the wafer 100 can be passed through the pedestal 122 (e.g., via the support column 124). Other parts of the temperature control system 140 can be located outside the plasma chamber 110. These parts are shown schematically as components 142 in FIG. 2 and can include, for example, a reservoir for liquid coolant, gas canisters, pumps, valves, pipes, additional sensors to sense, for example, temperatures and flow rates of the cooling fluids, and a temperature controller that receives data from the sensors and transmits control signals to operate various parts of the temperature control system 140. The components 142 can be coupled to parts of the temperature control system 140 included in the pedestal 122 via, for example, the support column 124, as illustrated in FIG. 2.

Still referring to FIG. 2, the pedestal 122 can include an electrode, which can be referred to as a bottom electrode or a lower electrode, and which can be configured to couple to various radio frequency (RF), direct current (DC), pulsed RF, and pulsed DC power supplies. For example, the pedestal 122 can include a bottom electrode 120 located below the wafer holder 105. The bottom electrode can be within the wafer holder 105. The bottom electrode 120 can be coupled to two RF power supplies: a first RF power supply 125 and a second RF power supply 130. More than one power supply can be used during plasma processing to provide flexibility in adjusting multiple plasma properties, such as plasma density, ionization rate, dissociation rate, and a voltage across a plasma sheath, which can determine a vertical velocity of an ion as it strikes the wafer 100. In some configurations, the bottom electrode 120 can be coupled to one power supply (as opposed to multiple power supplies). The power supply can be an RF power supply or a different power supply, such as a pulsed DC power supply. The bottom electrode 120 can be coupled to a reference potential, which can be referred to as ground GND. The bottom electrode 120 can be floating.

Still referring to FIG. 2, in addition to the bottom electrode 120, the plasma system 10 can be equipped with an upper electrode, which is referred to here as a target electrode 150. The target electrode 150 can be located inside the plasma chamber 110, above the bottom electrode 120. A lower portion of the target electrode 150, facing the wafer 100 on the wafer holder 105, can be a sputter target 152 including a target material. The sputter target 152 can be detachably attached to the target electrode 150.

A direct current superposition (DCS) function can be applied using the plasma system 10 to sputter deposit target material off the sputter target 152 onto the wafer 100, with plasma sustained between the target electrode 150 and the bottom electrode 120. To apply the DCS function, the target electrode 150 can be configured to be coupled to a DC bias power supply 165. During performing a deposition process, for example, the DC bias power supply 165 can apply a first DC bias to the target electrode 150, where the first DC bias biases the target electrode 150 negative relative to the bottom electrode 120. With the target electrode 150 biased negatively, positively charged ions can be attracted from the plasma sustained between the target electrode 150 and the bottom electrode 120 and strike the sputter target 152 with high kinetic energy. The ion bombardment can sputter target material off the sputter target 152. The sputtered target material can deposit on the wafer 100, which is held by the wafer holder 105 below the sputter target 152, as well as on walls of the plasma chamber 110.

The target electrode 150 can be coupled to an RF power supply, in addition to the DC bias power supply 165. For example, instead of coupling the first RF power supply 125 and the second RF power supply 130 to the bottom electrode 120 (as seen in FIG. 2), the first RF power supply 125 can be coupled to the target electrode 150 while the second RF power supply 130 remains coupled to the bottom electrode 120. In such configuration, the first DC bias can be superposed on the RF signal from the first RF power supply 125, to provide the DCS function.

Low temperature gas discharge plasma for processing the wafer 100 can be generated at a low pressure in the plasma chamber 110 by ionizing gas flowing through the plasma chamber 110 using, for example, RF power (referred to as RF source power) supplied by an RF power supply, such as the first RF power supply 125. Additional RF power (referred to as RF bias power) supplied by another RF power supply, such as the second RF power supply 130, can be used to adjust, for example, an angle distribution of ions incident on the wafer 100. In the example plasma system 10 in FIG. 2, both RF power supplies are coupled to the bottom electrode 120. However, as mentioned above, various configurations may be used. For example, the first RF power supply 125 can be coupled to the target electrode 150 while the second RF power supply 130 remains coupled to the bottom electrode 120.

Still referring to FIG. 2, the plasma system 10 can include a gas flow system 170 to establish a gas flow through the plasma chamber 110. The gas flow system 170 can include a gas delivery system 115 to supply gas to the plasma chamber 110, and a gas evacuation system 135 to remove gas from the plasma chamber 110 and maintain a desired low pressure (e.g., as instructed by a process recipe). Components of the gas delivery system 115 and the gas evacuation system 135 can include gas canisters, flow meters, throttle valves, one or more vacuum pumps (e.g., a mechanical roughing pump combined with one or more turbomolecular pumps), etc., for example. The plasma chamber 110 can be configured with multiple gas inlets and outlets to achieve a uniform gas flow over the wafer 100.

While using the plasma system 10 in an embodiment of the present disclosure, there are various parameters that can influence the plasma processing of the wafer 100, i.e., influence the physical and chemical interactions between the various regions of the major surface of the wafer 100 (e.g., the top surface, the bottom of each hole/opening, and the sidewalls), and a flux of particles (e.g., radicals and ions) from the plasma incident on the major surface of the wafer 100. The materials exposed to the plasma are parameters of interest, as described above. Also, there are parameters of interest related to plasma generation and processing. These can include the chemical composition of the incident flux, ion to radical ratio, ion energy and ion angle distribution, and plasma density, for example.

Some of the parameters related to the plasma generation and processing depend on the electrical signals coupled to the bottom electrode 120 and the target electrode 150 during the processing. As mentioned above, having more than one power supply can provide flexibility in adjusting the plasma properties. Typically, a higher frequency RF signal (e.g., about 60 MHz to about 4 GHz), referred to as RF source power, and a lower frequency RF signal (e.g., between 100 kHz and about 40 MHz), referred to as RF bias power, can be applied. RF source power can be coupled to plasma in the plasma chamber 110 to ignite and sustain the plasma. Generally, a high frequency RF signal can be used to adjust plasma properties, such as plasma density, ionization rate, and dissociation rate, and a low frequency RF signal can be used to control the flux the kinetic energy of ions striking the substrate. The RF bias power can be coupled to plasma in the plasma chamber 110 to control the vertical velocity of ions striking the wafer 100. Bias power can be provided as a continuous wave RF (CW-RF) signal. Bias power can be provided as a pulsed RF signal, a pulsed DC signal, or a DC signal.

Still referring to FIG. 2, the RF source power can be provided by the first RF power supply 125 and the RF bias power can be provided by the second RF power supply 130. Although, in this example of FIG. 2, both RF source power and RF bias power are coupled to the bottom electrode 120, it can be understood that various combinations are possible. For example, the RF source power can be coupled to the target electrode 150 while the RF bias power is coupled to the bottom electrode 120.

The first RF power supply 125 can include a tunable RF power source 131 with its output coupled to an impedance matching circuit 133 to suppress reflections and transfer power efficiently to the plasma at an operating RF frequency. The first RF power supply 125 can output a continuous wave RF (CW-RF) signal. The first RF power supply 125 can further include a pulse generator and a chopper circuit to output a pulsed RF signal.

The second RF power supply 130 can be similar to the first RF power supply 125. The second RF power supply 130 can include a tunable RF power source 132 with its output coupled to an impedance matching circuit 134. The second RF power supply 130 can also include additional circuitry to output a pulsed RF signal. The second RF power supply 130 can be replaced with a pulsed DC power supply or a DC power supply.

Still referring to FIG. 2, the target electrode 150 can include the sputter target 152, which can be used to sputter deposit target material when a deposition process and/or a deposition-etch process is performed. Thus, the target electrode 150 can be configured to be coupled to the DC bias power supply 165.

To improve process yield, it can be desirable to generate the plasma uniformly across the entire major surface of the wafer 100. However, along an edge of the wafer 100, electromagnetic (EM) properties (such as, conductivity, permittivity, and permeability) can change abruptly in a radial direction because of material discontinuity across a boundary between the wafer 100 and the wafer holder 105. The discontinuities can cause nonuniformity in radial components of the EM field in the vicinity of the edge. Hence, there can be a respective radial nonuniformity in plasma processing in an annular edge region of the wafer 100, resulting in an undesirably higher yield loss of the semiconductor devices fabricated in the edge region of the wafer 100. Uniformity of the EM field can be extended radially beyond the edge by surrounding the wafer 100 with, for example, a dielectric ring (referred to as a focus ring) having, for example, a desired permittivity.

Still referring to FIG. 2, the plasma system 10 can include a focus ring 154 placed over a disc-shaped bottom electrode 120. The wafer 100 can be positioned centrally within the focus ring 154. Generally, dimensions of the focus ring 154, for example, a radial width and a vertical height above the wafer 100 can be optimized to maintain and extend the uniformity of the EM field to achieve uniform plasma processing in the edge region of the wafer 100. Typically, there can be a clearance of a few hundreds of microns to a few millimeters between the edge of the wafer 100 and the focus ring 154. The focus ring 154 may can include a silicon-based material (e.g., silicon, silicon oxide, and silicon carbide), a carbon-based material, or a metal oxide, for example.

A deposition process for embodiment of the present disclosure can be engineered to result in deposition/formation of an oxide liner using the DCS function by sputtering the sputter target 152 (e.g., sputter target 152 including silicon). The sputtered silicon can then be deposited onto an intermediate structure of the wafer 100. Such deposition process can combine physical sputtering and plasma-enhanced deposition using a DCS sputtering process including sputtering of silicon from a solid target mounted on the upper electrode 150 while applying DC bias to influence the film properties of an oxide liner formed on an intermediate structure of the wafer 100. The upper electrode 150 can include a sputter target 152 that is or includes silicon (or another base material for forming a non-low-k dielectric or oxide material) and the upper electrode 150 can be connected to a DC power supply. The lower electrode 120 (and the wafer holder 105) can be connected to an RF power supply and a DC bias control (for superposition). A gas flow into the plasma chamber 110 can include an inert gas (e.g., argon) for the plasma and sputtering, and later an oxygen-containing gas (e.g., ambient air, O₂, N₂O, or some combination thereof) for converting the deposited silicon to silicon dioxide, for example. In some embodiments, for a DCS sputtering process for deposition, deposition-etching, etching, or some combination thereof, a gas species such as pure argon (Ar) or argon/nitrogen (Ar/N₂) can be used to prevent damage to the low-k dielectric layer while using the following plasma chamber parameters (for example): pressure in a range of 10 mTorr to 100 mTorr, DCS from −200 V to −1000 V, and source RF power of 100 W to 500 W. The inert gas (e.g., argon flowed at about 50 to 200 sccm) can act as the primary sputtering gas. The oxygen-containing gas (e.g., air, O₂, and/or N₂O flowed at about 10 to 100 sccm) can act as the reactive gas to convert deposited silicon to silicon dioxide (and to adjust stoichiometry as needed). RF power (e.g., 13.56 MHz at about 100 to 500 W) on the lower electrode 120 can generate plasma above the wafer 100 in the plasma chamber 110, can control ion energy in the plasma chamber 110, and can provide substrate biasing. DC power of about −300 to −800 volts can be applied on the upper electrode 150 (i.e., on the sputtering target 152). DC superposition bias of about −50 to −400 volts can be applied on the lower electrode 120 (i.e., on the wafer 100 via the wafer holder 105) for tuning ion assistance. Pressure in the plasma chamber 110 can be about 1 to 10 mTorr, at a relatively lower pressure to improve sputtering efficiency. The wafer 100 can be at a temperature between room temperature (not heated) to 400° C. Higher temperature can improve film quality, but lower temperatures can be used to conserve or control thermal budget. While applying the RF power to the lower electrode 120 to create plasma of the inert gas (e.g., argon), DC power can be applied to the upper electrode 150 to initiate sputtering of the silicon from the sputter target 152. After forming a silicon layer on the intermediated structure to a sufficient or desired thickness, the oxygen-containing gas (e.g., air, O₂, and/or N₂O) can be introduced and tuned as needed to convert the silicon layer to a silicon dioxide layer (and to adjust the oxide stoichiometry as needed). Superimposed DC bias on the lower electrode 120 (i.e., on the wafer 100) can be used to control ion bombardment and film properties during the formation of an oxide liner 60 on an intermediate structure of the wafer 100. The deposition of the oxide liner 60 can be minimal to provide partial or complete coverage of sidewalls of a via hole 40, which can be 1 to 3 nm in thickness for example, which can take about 1 to 3 minutes of deposition time (e.g., about 1-10 nm/min), depending on the plasma-chamber parameters used. Increasing RF power and lowering pressure can result in higher deposition rate. Increasing DC bias on the upper electrode 150 can result in enhanced or greater sputtering yield.

Alternatively and/or in addition for embodiment of the present disclosure, a deposition-etch process can be engineered to result in concurrent deposition and etching at different regions of the major surface of the wafer 100. Using the DCS function, a lining can form over the flat top portion and sidewalls while, at the same time, the bottom of each hole or opening can be etched. Because the major surface of the wafer 100 and the exposed surface of the sputter target 152 are on opposite sides of the plasma used for the sputtering, the plasma can be double used to concurrently etch at the bottom of each hole/opening by configuring the plasma to provide a flux of ions to the wafer 100 that may selectively activate a material at the bottom of each hole/opening for etching to occur there.

Still referring to FIG. 2, the plasma system 10 can include a system controller 190. The system controller 190 can include, for example, one or more processors coupled to one or more memory devices. During operation, the processor(s) can import, from the memory device(s), instructions from a process recipe and feedback data from sensors in the plasma system 10 and execute the instructions. By executing the instructions, the system controller 190 can generate appropriate control signals for configuring and operating various components and sub-systems of the plasma system 10. The system controller 190 can be coupled to a communication network of the plasma system 10 to send the generated control signals synchronously to control the various components and sub-systems of the plasma system 10 for a method embodiment of the present disclosure. For example, the system controller 190 can coupled to a communication network configured to transmit control signals to the gas delivery system 115, the gas evacuation system 135, the first RF power supply 125, the second RF power supply 130, the temperature control system 140, and the DC bias power supply 165. Through such communication network, the system controller 190 can use the control signals to synchronously adjust relevant process parameters such as gas flow rates, pressure in the plasma chamber 110, frequencies and power levels of the RF source signal and the RF bias signal, temperature of the wafer 100, and the DC bias applied to the target electrode.

FIGS. 3A to 3F are cross-section views illustrating intermediate structures of a semiconductor device, having interconnect levels M0 and M1, made using a method according to an embodiment of the present disclosure. Referring to FIG. 3A, a first intermediate structure 11 can include multiple levels/layers of insulating layers on a substrate 20. In the present disclosure, substrate 20 can be a very generic and simplified representation of any semiconductor structures that can be below the BEOL structure, such as a wafer, transistors, logic devices, power devices, digital circuits, analog circuits, or any combination thereof, for example, or any suitable/feasible structure, as can be apparent to one of ordinary skill in the art for which the present disclosure pertains (and thus the details of which are omitted here). Hence, the simplified representation of the substrate 20 in the drawings is not intended to be necessarily limiting.

Referring to FIG. 3A, a first intermediate structure 11 can include an M0 level including an underlying conductive structure 30. The underlying conductive structure 30 in the drawings is shown as a single block of material merely to simplify the drawings, as the underlying conductive structure 30 in some embodiments can include multiple layers of multiple materials (e.g., barrier layer, adhesion layer, metal fill, etc.) or any suitable/feasible structure, as can be apparent to one of ordinary skill in the art for which the present disclosure pertains (and thus the details of which are omitted here). Hence, the simplified representation of the underlying conductive structure 30 in the drawings is not intended to be necessarily limiting. In some embodiments, some of or most of a top surface of the underlying conductive structure 30 can be a metal material, such as ruthenium, copper, cobalt, tungsten, or any combination thereof, for example.

Referring to FIG. 3A, a first dielectric layer 50 can include a via hole 40 formed therein at interconnect level M1. In some embodiments, the first dielectric layer 50 can be a single layer of one material, a single layer of a mix of multiple materials, multiple layers of one material, multiple layers of a same material or mix of multiple materials, or multiple layers of different materials, for example. In some embodiments, the material(s) of a given first dielectric layer 50 can be selected in view of providing acceptable dielectric properties (e.g., low-k), and fitting within the process integration flow and device electrical characteristics (e.g., thermal budgets, stress inducing, non-stress inducing, thermal stress mismatching, adhesion, electrical properties, parasitic capacitance, etc.). In some embodiments, such material(s) of a given first dielectric layer 50 can include any suitable low-k dielectric material (i.e., material having a dielectric constant less than 3.9) (e.g., flowable oxide, oxide gel, including large air pockets, porous, etc.), for example.

In some embodiments, such material(s) of a given first dielectric layer 50 can include a low-k dielectric material, such as silicon oxycarbide (SiOC), silicon oxycarbonitride (SiOCN), fluorinated silicon dioxide (FSG), organosilicate glass (OSG), silicon-carbon-oxygen-hydrogen (SiCOH), porous SiCOH, hydrogen silsesquioxane (HSQ), Methylsilsesquioxane (MSQ), nanoporous silicon dioxide, organic polymer having a third dielectric constant less than 2.6, silica-based aerogel having a fourth dielectric constant less than 2.4, spin-on organic material having a fifth dielectric constant less than 2.6, benzocyclobutene (BCB), or organosilicate material having a sixth dielectric constant less than 2.7, layers thereof, mixtures thereof, laminates thereof, or generally any combination thereof, for example.

Thus, because the first dielectric layer 50 of an embodiment can include any number or combination of layers and materials (e.g., low-k dielectric material, etch stop layer, barrier layer, etc.), or any suitable/feasible structure (as can be apparent to one of ordinary skill in the art for which the present disclosure pertains and hence the details of which are omitted here), the simplified representation of the first dielectric layer 50 in the drawings can be considered a simplified illustration and is not intended to be necessarily limiting.

In some embodiments, the first dielectric layer 50 can have a thickness in a range of 30 nm to 100 nm, while the via hole 40 can have a critical dimension (e.g., diameter) in a range of 5 nm to 20 nm, which can be a relatively high aspect ratio via hole. For example, in some embodiments, the first dielectric layer 50 can have a thickness of about 60 nm and the via hole 40 can have a diameter of about 10 nm.

Photolithography and patterning masks can be used and removed in a process flow for forming the via hole 40 of FIG. 3A, as can be apparent to one of ordinary skill in the art, and thus the details of which are omitted herein.

Referring to FIGS. 3B and 3C, an oxide liner 60 can be formed or deposited on the first intermediate structure 11 and on sidewalls of the via hole 40 in a plasma chamber using at least one direct current superposition (DCS) process, such as depositing silicon by sputtering a target including silicon to form silicon dioxide (e.g., as described above regarding FIG. 2), depositing-etching by sputtering a target including silicon to form silicon dioxide (e.g., as described above regarding FIG. 2), or any combination thereof, for example. In some embodiments, the via hole 40 can be etched in a first plasma chamber 110 (see, e.g., FIG. 2) using a first set of plasma-chamber parameters, and then without necessarily removing the wafer 100 from the first plasma chamber 110, forming or depositing an oxide liner 60 (see, e.g., FIGS. 3B and 3C) on sidewalls of the via hole 40 using at least one DCS process (e.g., as described above relating to FIG. 2) with a second set of plasma-chamber parameters in the first plasma chamber 110 (e.g., with a same plasma system 10). In such example, the second set of plasma-chamber parameters can differ from the first set of plasma-chamber parameters. In such example, the oxide liner 60 can include an oxide material that differs from the low-k dielectric material of the first dielectric layer. For example, the oxide liner 60 can be made of silicon dioxide having a dielectric constant of 3.9 or more, and the first dielectric layer 50 can be made of a low-k dielectric material having a dielectric constant of less than 3.9.

Referring to FIGS. 3B and 3C, in some embodiments, a first stage of forming an oxide liner 60 can include depositing/forming the oxide liner 60 (as described above for example) (see, e.g., FIG. 3B) and a second stage of removing (e.g., etching) a hole-bottom portion of the oxide liner 60 at a bottom of the via hole 40 (see, e.g., FIG. 3C) using a third set of plasma-chamber parameters in the plasma chamber 110 (without necessarily removing the wafer 100 from the plasma chamber 110), such that at least part of the oxide liner 60 remains on at least part of the sidewalls of the via hole 40. In such example, the third set of plasma-chamber parameters can differ from the first set of plasma-chamber parameters and/or the second set of plasma-chamber parameters. For example, after depositing an oxide liner 60 as shown in FIG. 3B in a first stage, the hole-bottom portion of oxide liner 60 can be removed by sputtering using a DCS function in a deposition-etch process. In such example, during the second stage as illustrated in FIG. 3C, some material of the oxide liner 60 can be additionally deposited on a top portion 61 of the oxide liner 60 and on a sidewall portion 62 of the oxide liner 60, while some material from the top portion 61 of the oxide liner 60 is removed (which can be a net zero addition of material, for example) and while material of the oxide liner 60 is sputtered and removed from a top surface of the underlying conductive structure 30 and redeposited (at least to some extent) on the sidewall portion 62 of the oxide liner 60. By tuning the deposition-etch process using DCS function and RF power for controlling the plasma and voltage bias, the second stage can result in removal of material at the bottom of the via hole 40, while retaining at least some of the material at the top portion 61 of the oxide liner 60 on a top surface 55 of the first dielectric layer 50.

In some embodiments, the third set of plasma-chamber parameters for a second stage of removing a hole-bottom portion of the oxide liner 60 at a bottom of the via hole 40 with a DCS etch can include the following: pressure ranging from 10 mTorr to 100 mTorr, DCS voltage ranging from −200V to −1000V, source RF power ranging from 100 W to 500 W, bias power ranging from 20 W to 200 W, and using gases such as CF₄/C₄F₈ or NF₃, for example.

In some embodiments, the removing a hole-bottom portion of the oxide liner 60 at a bottom of the via hole 40 can be a part of a DCS process (e.g., deposition-etch process described above and/or etching process described above), can be a separate etching process (e.g., RIE using argon) without DCS, can be a separate etching process with DCS (as described in the immediately prior paragraph), or can be a part of a single all-encompassing DCS process for forming the oxide liner 60 (e.g., deposition-etch DCS process described above).

Referring to FIG. 3D, a conductive material for an interconnect structure 70 can be formed directly on the oxide liner 60 and directly on a top surface of the underlying conductive structure 30 (at the bottom of the via hole 40). The conductive material for the interconnect structure 70 can be ruthenium. In some embodiments, metal material(s) of the interconnect structure 70 can include ruthenium, molybdenum, niobium, tungsten, tantalum, aluminum, alloys thereof, layers thereof, mixtures thereof, laminates thereof, or generally any combination thereof, for example. By using materials such as ruthenium and/or molybdenum, the use of a barrier layer can be omitted with respect to dielectric layer materials. However, while the use of ruthenium and/or molybdenum can be desirable for filling smaller diameter and/or higher aspect ratio via holes, other issues in the process flow using such materials can arise, such as oxidation and interface resistance, which can introduce additional processing steps and intervening layers.

In the example embodiments described in the present disclosure, the conductive material for an interconnect structure 70 will be ruthenium. However, in other potential embodiments, the conductive material for an interconnect structure 70 can be other materials, such as an alloy of ruthenium or ruthenium combined with another material, for example.

Referring to FIG. 3D, the via hole 40 can be overfilled with ruthenium such that the ruthenium is formed on an oxide-liner top surface 65 of the third intermediate structure 13 of FIG. 3C, to form a fourth intermediate structure 14 of FIG. 3D. The ruthenium of the interconnect structure 70 can be formed using any suitable deposition process, such as physical vapor deposition (PVD), plasma enhanced physical vapor deposition (PEPVD), chemical vapor deposition (CVD), plasma enhanced chemical vapor deposition (PECVD), atomic layer deposition (ALD), or any combination thereof, for example.

Still referring to FIG. 3D, a top oxide liner portion 61 of the oxide liner 60 can be between an overburden portion of the interconnect structure 70 and the first dielectric layer 50. A via sidewall liner portion 62 of the oxide liner 60 can be between the interconnect structure 70 and the first dielectric layer 50.

Still referring to FIG. 3D, the interconnect structure 70 can be directly on the underlying conductive structure 30. By having the interconnect structure 70 formed directly on the underlying conductive structure 30, a contact resistance between the interconnect structure 70 and the underlying conductive structure 30 can be optimized, for example. In some embodiments, a top surface of the underlying conductive structure 30 can be cleaned and/or submitted to a pretreatment process (e.g., to remove surface oxidation) prior to or immediately prior to depositing the ruthenium of the interconnect structure 70, to provide better electrical contact of the interconnect structure 70 with the underlying conductive structure 30.

Referring to FIG. 3E, a chemical mechanical polishing (CMP) can be performed, for example, to remove the overburden of the ruthenium, to form a fifth intermediate structure 15. As shown in FIG. 3E, a top surface 75 of the interconnect structure 70 can be planarized with a top surface 65 of the oxide liner 60, such that the top oxide liner portion 61 is exposed. In some embodiments, part of or all of the top oxide liner portion 61 of the oxide liner 60 can remain in place, such that subsequent structures formed on the fifth intermediate structure 15 can be formed directly on the top oxide liner portion 61 of the oxide liner 60.

Referring to FIG. 3F, optionally, part of, most of, or all of the top oxide liner portion 61 shown in FIG. 3E can be removed by continuing a CMP operation, which can include changing CMP chemical slurry and/or polishing pressure and/or polishing speed to avoid damage to the low-k material of the first dielectric layer 50. Thus, as illustrated in FIG. 3E, a top surface 75 of the interconnect structure 70 can be planarized with a top surface 55 of the first dielectric layer 50, to form a sixth intermediate structure 16. Thus, subsequent structures can be formed on the sixth intermediate structure 16 (e.g., directly on the first dielectric layer 50).

By having an oxide liner 60 (e.g., silicon dioxide having a dielectric constant of 3.9 or more) between the interconnect structure 70 (e.g., ruthenium via plug) and the low-k material of the first dielectric layer 50, the adhesion strength of the interconnect structure 70 with the oxide liner 60 can be improved (e.g., relative to ruthenium formed directly on a low-k dielectric material) so that the interconnect structure 70 does not become partially dislodged, moved, displaced, or fully dislodged during a CMP operation to remove the overburden metal material and planarize the top surfaces. Although the process flow described for FIGS. 3A to 3F is for a via hole, the same process flow can be applied for a trench.

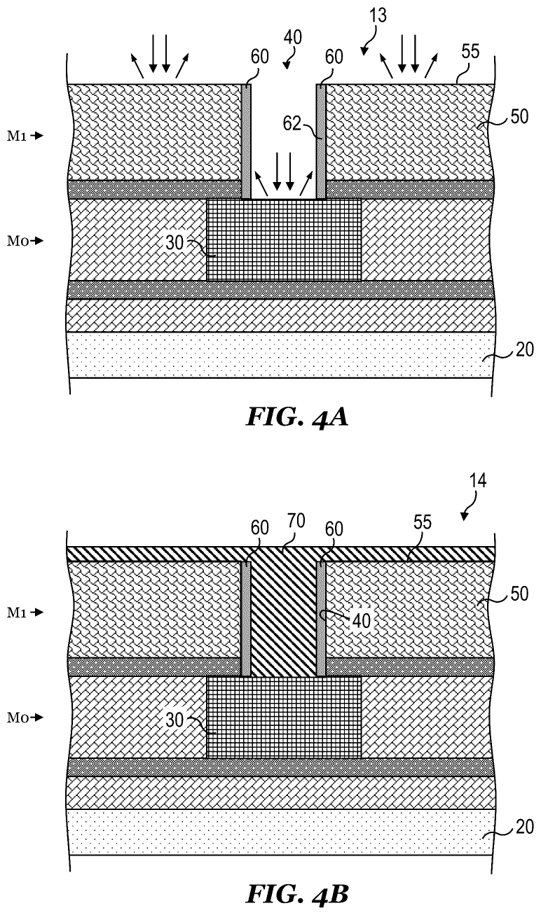

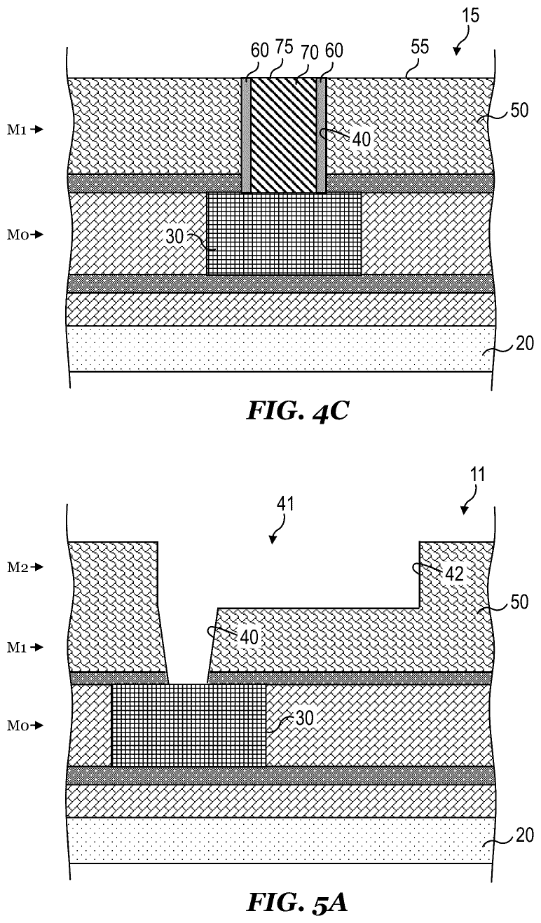

FIGS. 4A to 4C are cross-section views illustrating intermediate structures of a semiconductor device made using a method according to an embodiment of the present disclosure. Beginning with a second intermediate structure 12 of FIG. 3B, for example, an operation for removing a bottom portion of the oxide liner 60 to expose a top surface of the underlying conductive structure 30 at the bottom of the via hole 40 can be performed using a process as described above regarding FIG. 3C, except that plasma-chamber parameters for the plasma system 10 can be varied, to form a third intermediate structure of FIG. 4A.

Referring to FIG. 4A, part of, most of, or all of the oxide liner 60 can be removed from a top surface 55 of the first dielectric layer 50. In some embodiments, in a second stage discussed above regarding FIG. 3C, the plasma-chamber parameters can be tuned to be more of an etching stage to anisotropically sputter and remove material of the oxide liner 60 from the top surface 55 of the first dielectric layer 50 and to sputter and remove material of the oxide liner 60 from a top surface of the underlying conductive structure 30 (i.e., a hole-bottom portion of the oxide liner 60 at a bottom of the via hole 40), for example. In such example, this second stage can be performed in the plasma chamber 110 without necessarily removing the wafer 100 from the plasma chamber 110 after the first stage of depositing the oxide liner 60 (e.g., using a third set of plasma-chamber parameters), for example. In some embodiments, a second stage of forming an oxide liner 60 (e.g., after a first stage of depositing a conformal layer for the oxide liner 60 as illustrated in FIG. 3B), a reactive ion etching (RIE) can be performed to anisotropically remove portions of the oxide liner 60 on horizontally-oriented surfaces more than vertically-oriented surfaces (e.g., removing from the bottom of the via hole 40 and the top surface 55 of the first dielectric layer 50), for example. Such RIE can be performed in a same plasma chamber 110 as used for the deposition of the oxide liner 60, without necessarily removing the wafer 100 from the plasma chamber 110, for example.

In some embodiments, rather than a two stage process to form an oxide liner 60 (e.g., FIGS. 3B and 3C, or FIGS. 3B and 4A), an oxide liner 60 can be formed in a single stage using a deposition-etch process while using DCS function. For example, deposition by sputtering silicon material from a sputtering target 152 can result in deposition of that sputtered material on the first intermediate structure 11 of FIG. 3A, while a sputtering action of inert gas (e.g., argon) can simultaneously remove material from a top surface of the underlying conductive structure 30, and the plasma parameters can be held constant or varied during such deposition-etch process to tune the deposition to etching ratio, such that the oxide liner 60 forms mostly a sidewall portion 62 of the oxide liner 60 with some top portion 61 of the oxide liner 60 on a top surface 55 of the first dielectric layer 50 (see, e.g., structure shown in FIG. 3B) or with little, discontinuous, or no top portion 61 of the oxide liner 60 on a top surface 55 of the first dielectric layer 50 (see, e.g., structure shown in FIG. 4A), for example (and thus skipping the first stage of FIG. 3B). In such example embodiments, the single stage using a deposition-etch process while using DCS function can be performed in the same plasma chamber 110 as used for etching/forming the via hole 40 in the first dielectric layer 50, without necessarily removing the wafer 100 from the plasma chamber 110, by simply shifting/changing the plasma-chamber parameters.

Referring to FIG. 4B, as described above regarding FIG. 3D for example, a conductive material (e.g., ruthenium) for an interconnect structure 70 can be formed directly on the oxide liner 60 and directly on a top surface of the underlying conductive structure 30 (at the bottom of the via hole 40). The via hole 40 can be overfilled with ruthenium such that the ruthenium is formed on a top surface 55 of the first dielectric layer 50 of the third intermediate structure 13 of FIG. 4A, to form a fourth intermediate structure 14 of FIG. 4B.

Referring to FIG. 4C, a CMP can be performed, for example, to remove the overburden of the ruthenium, to form a fifth intermediate structure 15. As shown in FIG. 4C, a top surface 75 of the interconnect structure 70 can be planarized with a top surface 55 of the first dielectric layer 50, such that the first dielectric layer 50 is exposed.

Referring to FIGS. 3A to 3F and 4A to 4C, for example, when implementing an embodiment of the present disclosure, a size of a via hole 40 formed in the first dielectric layer 50 (see, e.g., FIG. 3A), can be made with a larger diameter (or planar cross-section critical dimension width) to compensate for a specified or expected thickness of the oxide liner 60, such that the interconnect structure 70 results in a desired or targeted or specified size (e.g., diameter, width). Alternatively, using an embodiment of the present disclosure, a diameter, width, or critical dimension of a given via hole 40 can be shrunk relative to a mask used for patterning the via hole 40 by adding the oxide liner 60, which can be an advantage for achieving smaller geometry in a BEOL structure. In an embodiment of the present disclosure, a thickness of an oxide liner 60 can be adjusted and tuned to provide a desired or targeted or specified size of a resulting interconnect structure 70, by adjusting the plasma-chamber parameters during the formation of the oxide liner 60 (see, e.g., FIG. 3B) and/or by adjusting the plasma-chamber parameters during the removal of the oxide liner 60 at the bottom of the via hole 40 (see, e.g., FIGS. 3C and 4A). Although the process flow described for FIGS. 4A to 4C is for a via hole, the same process flow can be applied for a trench.

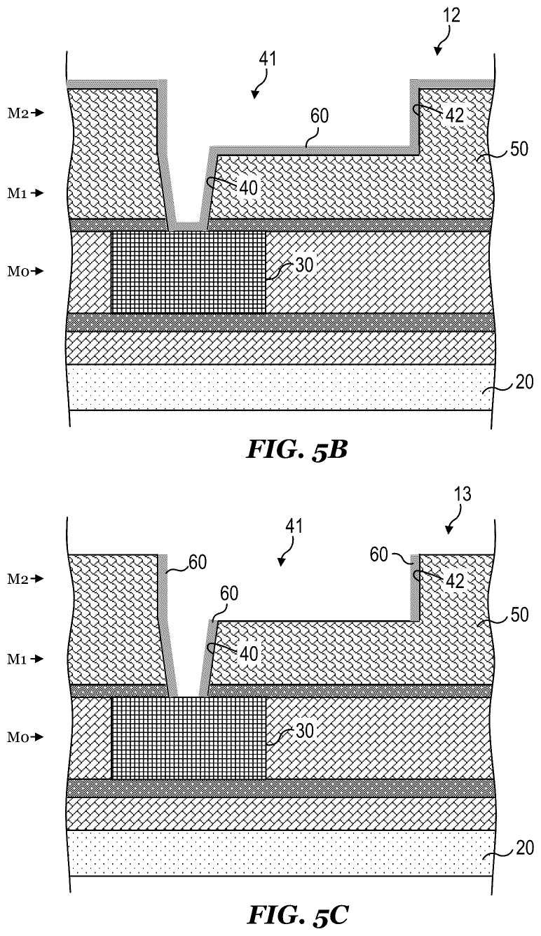

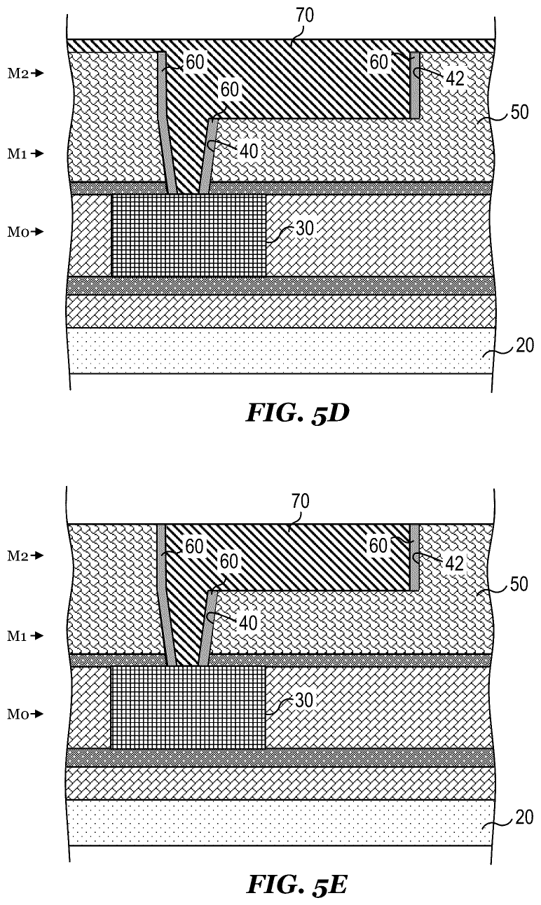

FIGS. 5A to 5E are cross-section views illustrating intermediate structures of a semiconductor device, having interconnect levels M0, M1, and M2, with a dual damascene structure, made using a method according to an embodiment of the present disclosure.

Referring to FIG. 5A, a first intermediate structure 11 can include an M0 level including an underlying conductive structure 30. A first dielectric layer 50 can include a first hole 41 formed therein using a dual damascene process flow. The first hole 41 can include a via hole 40 at interconnect level M1 and a trench 42 at interconnect level M2. The trench 42 can be contiguous with the via hole 40. First-hole sidewalls of the first hole 41 can include trench sidewalls of the trench 42 and via sidewalls of the via hole 40.

Referring to FIGS. 5B and 5C, an oxide liner 60 can be formed on the first-hole sidewalls of the first hole 41. More specifically, an oxide liner 60 can extend continuously on at least part of the via sidewalls of the via hole 40 and on at least part of the trench sidewalls of the trench 42. The oxide liner 60 of FIGS. 5B and 5C can be formed using one of the methods described above relating to FIGS. 3B and 3C, or FIGS. 3B and 4A, for forming a third intermediate structure 13, as shown in FIG. 5C for example. The bottom of the via hole 40 can be opened to the underlying conductive structure 30 (so that the underlying conductive structure 30 can be exposed at a top surface of the underlying conductive structure 30). In some embodiments, the oxide liner 60 can remain partially or fully or continuously on upward facing surfaces of the first dielectric layer 50, for example (as described above relating to FIG. 3C). The amount of oxide liner 60 remaining on upward facing surfaces of the first dielectric layer 50 can be varied by tuning the plasma-chamber parameters during the deposition of the oxide liner 60 and/or during the removal of the oxide liner 60 at the bottom of the via hole 40, for example.

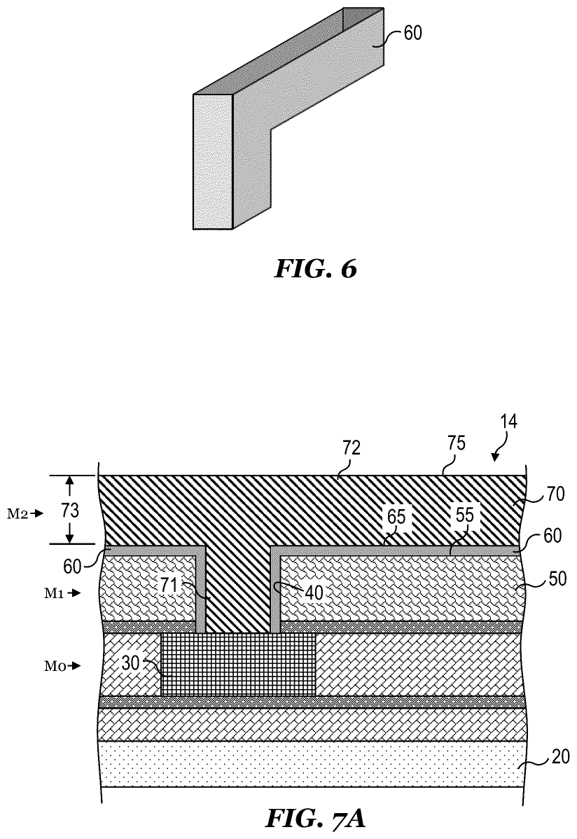

FIG. 6 is a perspective view of the oxide liner of FIG. 5C, according to an embodiment of the present disclosure. The perspective view of FIG. 6 illustrates that the oxide liner 60 in a dual damascene embodiment can generally have an “L” shape, for example.

Referring to FIGS. 5D and 5E, an interconnect structure 70 (e.g., of ruthenium material) can be deposited and planarized, as described above regarding FIGS. 3D to 3F, and/or regarding FIGS. 4B to 4C, for example.

Referring to FIG. 5E, by having an oxide liner 60 (e.g., silicon dioxide having a dielectric constant of 3.9 or more) between the interconnect structure 70 (e.g., ruthenium via plug and ruthenium line) and the low-k material of the first dielectric layer 50, the adhesion strength of the interconnect structure 70 with the oxide liner 60 can be improved (e.g., relative to ruthenium formed directly on a low-k dielectric material) so that the interconnect structure 70 does not become partially dislodged, delaminated, moved, displaced, or fully dislodged during a CMP operation to remove the overburden metal material and planarize the top surfaces. Using an embodiment of the present disclosure, a dual damascene structure with an interconnect structure 70 made of ruthenium can be formed in a low-k dielectric material of a first dielectric layer 50 while improving structural integrity of the interconnect structure 70 during CMP operations, which can prevent line wiggle or trench line displacement. Thus, using an embodiment of the present disclosure can improved production yield and device reliability.

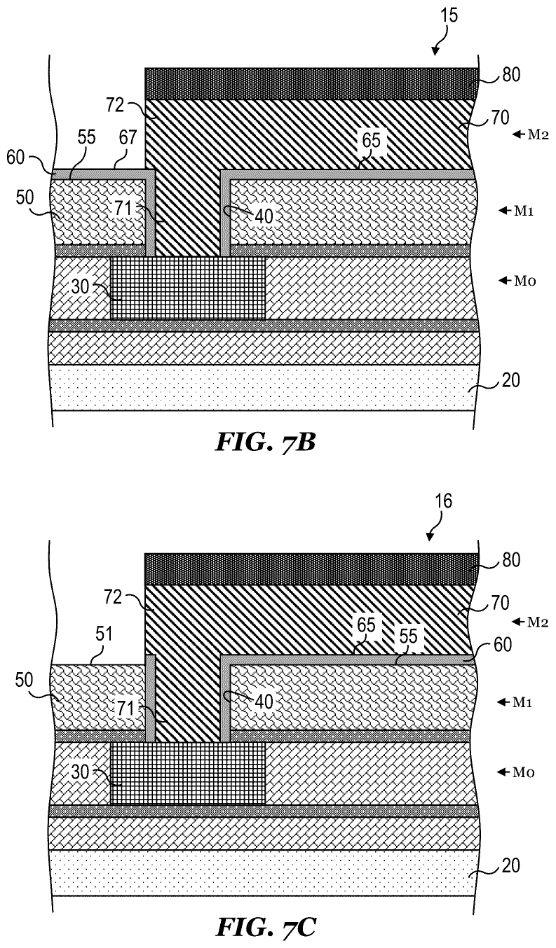

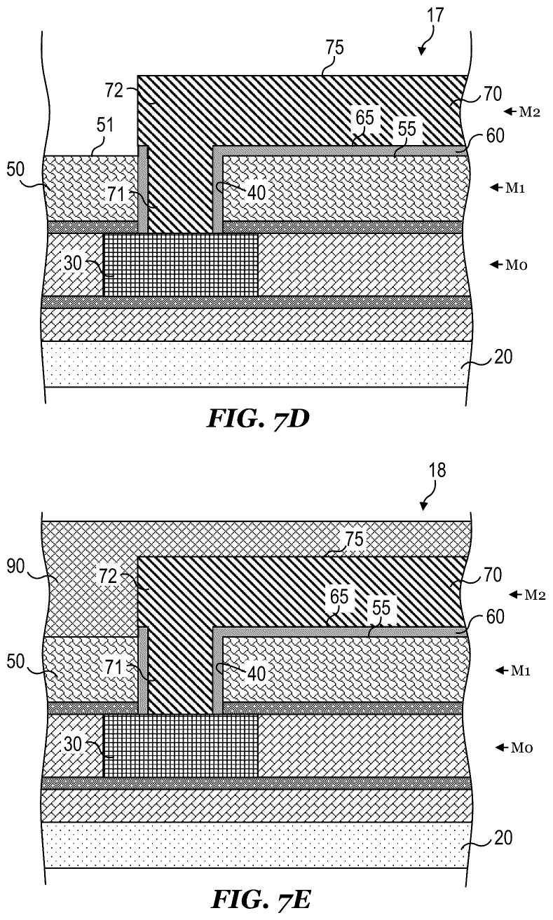

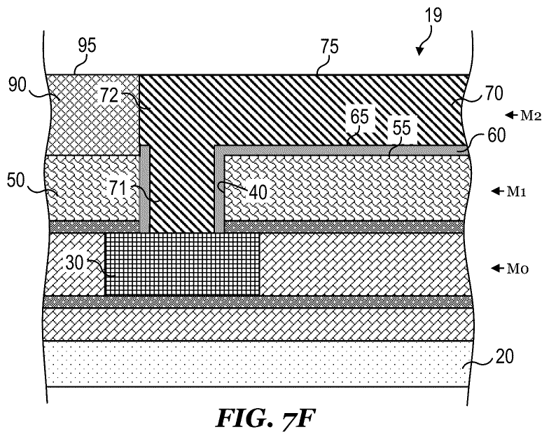

FIGS. 7A to 7F are cross-section views illustrating intermediate structures of a semiconductor device, having interconnect levels M0, M1, and M2, made using a subtractive semi-damascene method according to an embodiment of the present disclosure. Beginning with a third intermediate structure 13 of FIG. 3C, for example (e.g., formed as described above regarding FIGS. 3A to 3C), a conductive material for an interconnect structure 70 can be formed directly on the oxide liner 60, to form a fourth intermediate structure 14 of FIG. 7A. The conductive material for the interconnect structure 70 can be ruthenium.

Referring to FIG. 7A, the via hole 40 can be overfilled with ruthenium for an operation of forming an interconnect structure 70, such that a first thickness 73 of the ruthenium is formed on an oxide-liner top surface 65 of the third intermediate structure 13 of FIG. 3C, to form a fourth intermediate structure 14 of FIG. 7A. The oxide-liner top surface 65 can be above the via hole 40. A ruthenium top surface 75 of the ruthenium can be separated from the oxide-liner top surface 65 by the first thickness 73. For a subtractive semi-damascene process flow, the fourth intermediate structure 14 of FIG. 7A can have a blanket top surface 75 of ruthenium, for example. The ruthenium of the interconnect structure 70 can be formed using any suitable deposition process, such as physical vapor deposition (PVD), plasma enhanced physical vapor deposition (PEPVD), chemical vapor deposition (CVD), plasma enhanced chemical vapor deposition (PECVD), atomic layer deposition (ALD), or any combination thereof, for example.

Still referring to FIG. 7A, an interconnect structure 70 can have a via plug portion 71 at a first interconnect level M1 in the via hole 40, and a line portion 72 at a second interconnect level M2 extending directly on a top surface 65 of the oxide liner 60 (extending indirectly on the top surface 55 of the first dielectric layer 50). The via plug portion 71 can be contiguous and integral with the line portion 72 such that the line portion 72 is electrical connected with the underlying conductive structure 30 via the via plug portion 71. A via sidewall liner portion of the oxide liner 60 can be between the via plug portion 71 of the interconnect structure 70 and the sidewall of the via hole 40. A line liner portion of the oxide liner 60 can be between the line portion 72 of the interconnect structure 70 and a top surface 55 of the first dielectric layer 50.

Referring to FIGS. 7A and 7B, a mask 80 can be formed and patterned on the top surface 75 of the ruthenium of the interconnect structure 70, to form a fifth intermediate structure 15 of FIG. 7B. The mask 80 in the drawings is shown as a single block of material merely to simplify the drawings, as the mask 80 in some embodiments can include multiple layers of multiple materials or any suitable/feasible structure, as can be apparent to one of ordinary skill in the art for which the present disclosure pertains (and thus the details of which are omitted here). Hence, the simplified representation of the mask 80 in the drawings is not intended to be necessarily limiting. Photolithography and patterning of the mask 80 can be used.

Referring to FIG. 7B, using the mask 80 for establishing a pattern, the ruthenium of the interconnect structure 70 can be etched using any suitable etch chemistry, etching tool, and etching process, to form the fifth intermediate structure 15. In some embodiments, the ruthenium of the interconnect structure 70 can be etched using an oxide-based etch chemistry and reactive ion etching (RIE), for example. In some embodiments, the ruthenium of the interconnect structure 70 can be etched using an oxygen plasma and RIE, for example. The ruthenium of the interconnect structure 70 can be etched and patterned to expose a first-exposed-oxide-liner part 67 of the oxide liner 60 at the oxide-liner top surface 65 using the mask 80 to pattern the ruthenium forming the line portion 72 of the interconnect structure 70. The first-exposed-oxide-liner part 67 of the oxide liner 60 can be used as an etch-stop layer to protect the low-k dielectric material of the first dielectric layer 50 during the etching of the ruthenium of the interconnect structure 70. A low-k material of the first dielectric layer 50 can be more sensitive to chemical, structural, and/or electrical property changes from being exposed to etching chemicals used for etching the ruthenium. The first-exposed-oxide-liner part 67 of the oxide liner 60 can experience changes in chemical, structural, and/or electrical properties from being exposed to etching chemicals used for etching the ruthenium, but this first-exposed-oxide-liner part 67 can be less critical for changes than the low-k dielectric material of the first dielectric layer 50, and/or this first-exposed-oxide-liner part 67 can be removed in a subsequent operation, for example.

Referring to FIG. 7C, optionally, the first-exposed-oxide-liner part 67 of the oxide liner 60 adjacent the line portion 72 of the interconnect structure 70 (see FIG. 7B) can be removed to expose a first-exposed-dielectric-layer part 51 of the first dielectric layer 50 at the first-dielectric-layer top surface 55 of the first dielectric layer 50 adjacent the line portion 72 of the interconnect structure 70, to form a sixth intermediate structure 16. In some embodiments, the ruthenium of the interconnect structure 70 can be etched with a first etch chemistry that is selective to etching the ruthenium of the interconnect structure 70 much faster than the oxide liner 60 (see, e.g., FIG. 7B), and then the oxide liner 60 can be etched with a second etch chemistry to remove the first-exposed-oxide-liner part 67 of the oxide liner 60 adjacent the line portion 72 of the interconnect structure 70 (as illustrated in FIG. 7C).

In some embodiments, the first-exposed-oxide-liner part 67 of the oxide liner 60 shown in FIG. 7A can remain for subsequent operations to form subsequent intermediate structures, which is why it can be optional to remove it.

Referring to FIG. 7D, the mask 80 can be removed from a top surface 75 of the interconnect structure 70, to form a seventh intermediate structure 17. In some embodiments, the mask 80 can be removed before etching the first-exposed-oxide-liner part 67 of the oxide liner 60 adjacent the line portion 72 of the interconnect structure 70. In some embodiments, the mask 80 can be removed after etching the first-exposed-oxide-liner part 67 of the oxide liner 60 adjacent the line portion 72 of the interconnect structure 70. In some embodiments, part or all of the mask 80 can be removed while etching part or all of the first-exposed-oxide-liner part 67 of the oxide liner 60 adjacent the line portion 72 of the interconnect structure 70. The mask 80 can be removed by a wet clean, for example. An oxide hard mask can be removed using a diluted hydrofluoric acid (DHF), for example. The process used to remove the mask 80 can depend on the material(s) used for the mask 80 and the first dielectric layer 50, to avoid damaging the first dielectric layer 50 during the removal of the mask 80. The mask 80 can be removed using any suitable/feasible process, as can be apparent to one of ordinary skill in the art for which the present disclosure pertains (and thus more details of which are omitted here).

Referring to FIG. 7E, a second dielectric layer 90 can be formed or deposited on the seventh intermediate structure 17 of FIG. 7D, to form an eighth intermediate structure 18 in FIG. 7E. More specifically, a second dielectric layer 90 can be formed or deposited on the first-exposed-dielectric-layer part 51 of the first dielectric layer 50 and on the line portion 72 of the interconnect structure 70. A portion of the second dielectric layer 90 can be formed or deposited directly on the first-exposed-dielectric-layer part 51 of the first dielectric layer 50. A portion of the second dielectric layer 90 can be formed or deposited directly on the line portion 72 of the interconnect structure 70.

In some embodiments, the second dielectric layer 90 can be a single layer of one material, a single layer of a mix of multiple materials, multiple layers of one material, multiple layers of a same material or mix of multiple materials, or multiple layers of different materials, for example. In some embodiments, the material(s) of a given second dielectric layer 90 can be selected in view of providing acceptable dielectric properties (e.g., low-k), and fitting within the process integration flow and device electrical characteristics (e.g., thermal budgets, stress inducing, non-stress inducing, thermal stress mismatching, adhesion, electrical properties, parasitic capacitance, etc.). In some embodiments, such material(s) of a given second dielectric layer 90 can include a suitable silicon dioxide (SiO₂) and structural variations thereof (e.g., flowable oxide, gel, including large air pockets, porous, etc.), for example.

In some embodiments, such material(s) of a given second dielectric layer 90 can include a low-k dielectric material, such as silicon oxycarbide (SiOC), silicon oxycarbonitride (SiOCN), fluorinated silicon dioxide (FSG), organosilicate glass (OSG), silicon-carbon-oxygen-hydrogen (SiCOH), porous SiCOH, hydrogen silsesquioxane (HSQ), Methylsilsesquioxane (MSQ), nanoporous silicon dioxide, organic polymer having a third dielectric constant less than 2.6, silica-based aerogel having a fourth dielectric constant less than 2.4, spin-on organic material having a fifth dielectric constant less than 2.6, benzocyclobutene (BCB), or organosilicate material having a sixth dielectric constant less than 2.7, layers thereof, mixtures thereof, laminates thereof, or generally any combination thereof, for example.

Thus, because the second dielectric layer 90 of an embodiment can include any number or combination of layers and materials (e.g., low-k dielectric material, etch stop layer, barrier layer, etc.), or any suitable/feasible structure (as can be apparent to one of ordinary skill in the art for which the present disclosure pertains and hence the details of which are omitted here), the simplified representation of the second dielectric layer 90 in the drawings can be considered a simplified illustration and is not intended to be necessarily limiting.

Referring to FIG. 7F, a second-dielectric-layer top surface 95 of the second dielectric layer 90 and a line-portion top surface 75 of the line portion 72 of the interconnect structure 70 can be planarized (e.g., using CMP), to form a ninth intermediate structure 19.

In some embodiments, the second dielectric layer 90 can have a thickness in a range of 30 nm to 100 nm, for example. In some embodiments, the second dielectric layer 90 can have a thickness of about 60 nm, for example.

Referring to FIG. 7F, by having an oxide liner 60 (e.g., silicon dioxide having a dielectric constant of 3.9 or more) between the interconnect structure 70 (e.g., ruthenium via plug and ruthenium line) and the low-k material of the first dielectric layer 50, the adhesion strength of the interconnect structure 70 with the oxide liner 60 can be improved (e.g., relative to ruthenium formed directly on a low-k dielectric material) so that the interconnect structure 70 does not become partially dislodged, moved, displaced, or fully dislodged during a CMP operation to remove the overburden metal material and planarize the top surfaces. Using an embodiment of the present disclosure, a subtractive semi-damascene structure with an interconnect structure 70 made of ruthenium can be formed in a low-k dielectric material of a first dielectric layer 50 while improving structural integrity of the interconnect structure 70 during CMP operations, which can prevent line wiggle or trench line displacement. Thus, using an embodiment of the present disclosure can improved production yield and device reliability.

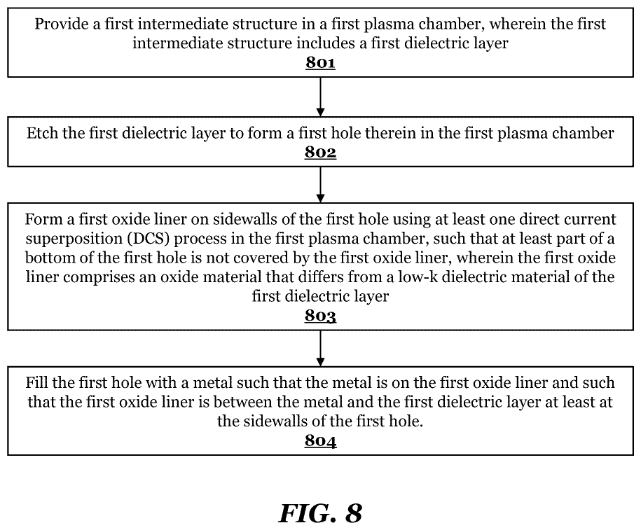

FIG. 8 illustrates a flow chart for a method implementing an oxide liner 60 in accordance with an embodiment of the present disclosure. In an embodiment, a method for making a semiconductor device includes providing a first intermediate structure in a first plasma chamber, where the first intermediate structure includes a first dielectric layer (box 801). The method includes etching the first dielectric layer to form a first hole therein in the first plasma chamber (box 802). The method includes forming a first oxide liner on sidewalls of the first hole using at least one direct current superposition process in the first plasma chamber, such that at least part of a bottom of the first hole is not covered by the first oxide liner, wherein the first oxide liner includes an oxide material that differs from a low-k dielectric material of the first dielectric layer (box 803). The method includes filling the first hole with a metal such that the metal is on the first oxide liner and such that the first oxide liner is between the metal and the first dielectric layer at least at the sidewalls of the first hole (box 804.

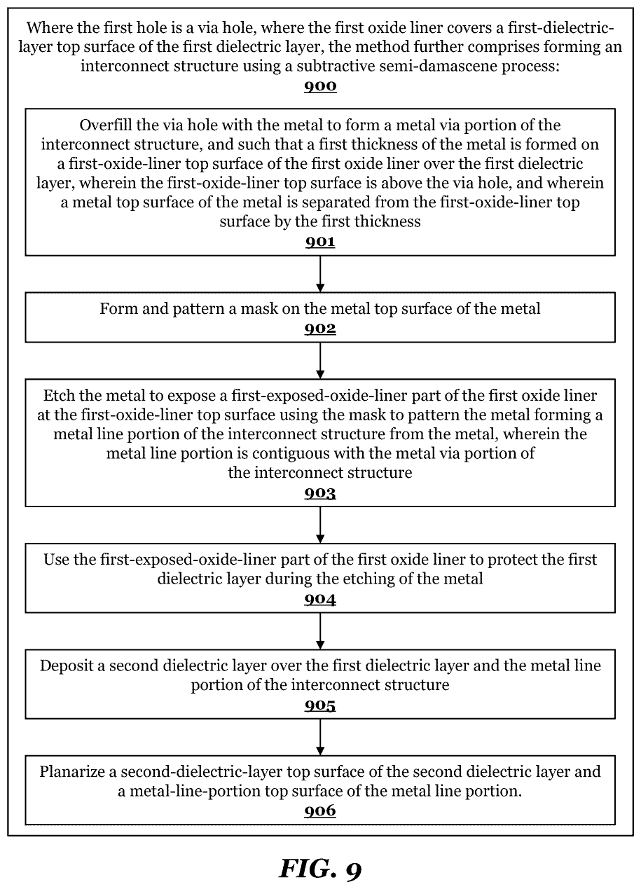

FIG. 9 illustrates a flow chart for a method implementing an oxide liner 60 in accordance with an embodiment of the present disclosure. In an embodiment, where the first hole is a via hole, where the first oxide liner covers a first-dielectric-layer top surface of the first dielectric layer, the method further includes forming an interconnect structure using a subtractive semi-damascene process (box 900). The subtractive semi-damascene process includes overfilling the via hole with the metal to form a metal via portion of the interconnect structure, and such that a first thickness of the metal is formed on a first-oxide-liner top surface of the first oxide liner over the first dielectric layer, wherein the first-oxide-liner top surface is above the via hole, and wherein a metal top surface of the metal is separated from the first-oxide-liner top surface by the first thickness (box 901). The subtractive semi-damascene process includes forming and patterning a mask on the metal top surface of the metal (box 902). The subtractive semi-damascene process includes etching the metal to expose a first-exposed-oxide-liner part of the first oxide liner at the first-oxide-liner top surface using the mask to pattern the metal forming a metal line portion of the interconnect structure from the metal, wherein the metal line portion is contiguous with the metal via portion of the interconnect structure (box 903). The subtractive semi-damascene process includes using the first-exposed-oxide-liner part of the first oxide liner to protect the first dielectric layer during the etching of the metal (box 904). The subtractive semi-damascene process includes depositing a second dielectric layer over the first dielectric layer and the metal line portion of the interconnect structure (box 905). The subtractive semi-damascene process includes planarizing a second-dielectric-layer top surface of the second dielectric layer and a metal-line-portion top surface of the metal line portion (box 906).

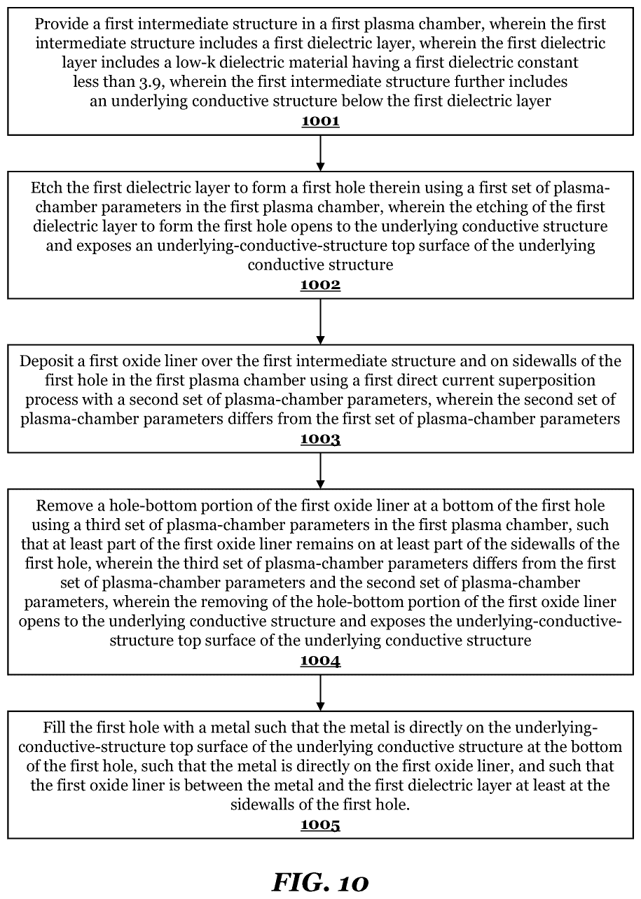

FIG. 10 illustrates a flow chart for a method implementing an oxide liner 60 in accordance with an embodiment of the present disclosure. In an embodiment, a method for making a semiconductor device includes providing a first intermediate structure in a first plasma chamber, wherein the first intermediate structure comprises a first dielectric layer, wherein the first dielectric layer comprises a low-k dielectric material having a first dielectric constant less than 3.9, wherein the first intermediate structure further comprises an underlying conductive structure below the first dielectric layer (box 1001). The method includes etching the first dielectric layer to form a first hole therein using a first set of plasma-chamber parameters in the first plasma chamber, wherein the etching of the first dielectric layer to form the first hole opens to the underlying conductive structure and exposes an underlying-conductive-structure top surface of the underlying conductive structure (box 1002). The method includes depositing a first oxide liner over the first intermediate structure and on sidewalls of the first hole in the first plasma chamber using a first direct current superposition process with a second set of plasma-chamber parameters, wherein the second set of plasma-chamber parameters differs from the first set of plasma-chamber parameters (box 1003). The method includes removing a hole-bottom portion of the first oxide liner at a bottom of the first hole using a third set of plasma-chamber parameters in the first plasma chamber, such that at least part of the first oxide liner remains on at least part of the sidewalls of the first hole, wherein the third set of plasma-chamber parameters differs from the first set of plasma-chamber parameters and the second set of plasma-chamber parameters, wherein the removing of the hole-bottom portion of the first oxide liner opens to the underlying conductive structure and exposes the underlying-conductive-structure top surface of the underlying conductive structure (box 1004). The method includes filling the first hole with a metal such that the metal is directly on the underlying-conductive-structure top surface of the underlying conductive structure at the bottom of the first hole, such that the metal is directly on the first oxide liner, and such that the first oxide liner is between the metal and the first dielectric layer at least at the sidewalls of the first hole (box 1005).

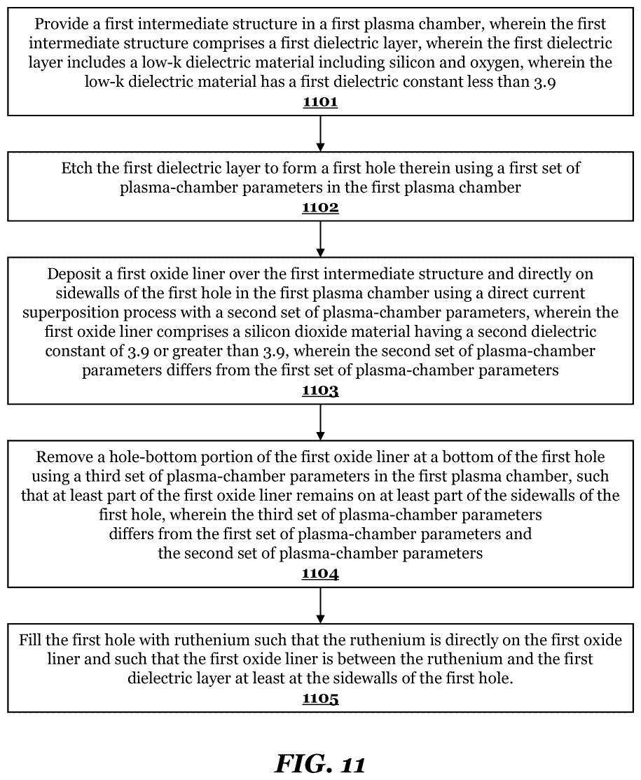

FIG. 11 illustrates a flow chart for a method implementing an oxide liner 60 in accordance with an embodiment of the present disclosure. In an embodiment, a method for making a semiconductor device includes providing a first intermediate structure in a first plasma chamber, wherein the first intermediate structure comprises a first dielectric layer, wherein the first dielectric layer comprises a low-k dielectric material including silicon and oxygen, wherein the low-k dielectric material has a first dielectric constant less than 3.9 (box 1101). The method includes etching the first dielectric layer to form a first hole therein using a first set of plasma-chamber parameters in the first plasma chamber (box 1102). The method includes depositing a first oxide liner over the first intermediate structure and directly on sidewalls of the first hole in the first plasma chamber using a direct current superposition process with a second set of plasma-chamber parameters, wherein the first oxide liner comprises a silicon dioxide material having a second dielectric constant of 3.9 or greater than 3.9, wherein the second set of plasma-chamber parameters differs from the first set of plasma-chamber parameters (box 1103). The method includes removing a hole-bottom portion of the first oxide liner at a bottom of the first hole using a third set of plasma-chamber parameters in the first plasma chamber, such that at least part of the first oxide liner remains on at least part of the sidewalls of the first hole, wherein the third set of plasma-chamber parameters differs from the first set of plasma-chamber parameters and the second set of plasma-chamber parameters (box 1104). The method includes filling the first hole with ruthenium such that the ruthenium is directly on the first oxide liner and such that the first oxide liner is between the ruthenium and the first dielectric layer at least at the sidewalls of the first hole (box 1105).

The embodiments described in FIGS. 8 to 11 may be implemented as further described using FIGS. 2 to 7F.

More example embodiments of the present disclosure are summarized here. Other embodiments can also be understood from the entirety of the specification as well as the claims filed herein.
Example 1. A method for making a semiconductor device, the method including: providing a first intermediate structure in a first plasma chamber, where the first intermediate structure includes a first dielectric layer, where the first dielectric layer includes a low-k dielectric material having a first dielectric constant less than 3.9; etching the first dielectric layer to form a first hole therein in the first plasma chamber; forming a first oxide liner on sidewalls of the first hole using at least one direct current superposition process in the first plasma chamber, such that at least part of a bottom of the first hole is not covered by the first oxide liner, where the first oxide liner includes an oxide material that differs from the low-k dielectric material of the first dielectric layer; and filling the first hole with a metal such that the metal is on the first oxide liner and such that the first oxide liner is between the metal and the first dielectric layer at least at the sidewalls of the first hole.
Example 2. The method of example 1, where the first intermediate structure further includes an underlying conductive structure below the first dielectric layer, where the etching of the first dielectric layer to form the first hole opens to the underlying conductive structure and exposes an underlying-conductive-structure top surface of the underlying conductive structure, where the forming of the first oxide liner opens to the underlying conductive structure and exposes the underlying-conductive-structure top surface of the underlying conductive structure, and where the filling of the first hole with the metal includes depositing the metal directly on the underlying-conductive-structure top surface of the underlying conductive structure at the bottom of the first hole.
Example 3. The method of one of examples 1 or 2, where the etching of the first dielectric layer to form the first hole therein is performed using a first set of plasma chamber parameters in the first plasma chamber; and where the forming of the first oxide liner includes: depositing the first oxide liner over the first intermediate structure and on the sidewalls of the first hole in the first plasma chamber using a first direct current superposition process with a second set of plasma chamber parameters, where the second set of plasma chamber parameters differs from the first set of plasma chamber parameters, and removing a hole-bottom portion of the first oxide liner at the bottom of the first hole using a third set of plasma chamber parameters in the first plasma chamber, such that at least part of the first oxide liner remains on at least part of the sidewalls of the first hole, where the third set of plasma chamber parameters differs from the first set of plasma chamber parameters and the second set of plasma chamber parameters.
Example 4. The method of one of examples 1 to 3, where the first intermediate structure further includes an underlying conductive structure below the first dielectric layer, where the etching of the first dielectric layer to form the first hole opens to the underlying conductive structure and exposes an underlying-conductive-structure top surface of the underlying conductive structure, where the removing of the hole-bottom portion of the first oxide liner opens to the underlying conductive structure and exposes the underlying-conductive-structure top surface of the underlying conductive structure, and where the filling of the first hole with the metal includes depositing the metal directly on the underlying-conductive-structure top surface of the underlying conductive structure at the bottom of the first hole.
Example 5. The method of one of examples 1 to 4, where the first hole includes a first trench and a first via hole, where the first trench is contiguous with the first via hole, where the forming of the first oxide liner includes forming the first oxide liner on a first sidewall of the sidewalls at the first via hole and forming the first oxide liner on a second sidewall of the sidewalls at the first trench, and where the filling of the first hole with the metal includes filling the first via hole with the metal and filling the first trench with the metal.
Example 6. The method of one of examples 1 to 5, where at least part of the metal is formed directly on the first dielectric layer at a first-trench-bottom portion of the first trench.
Example 7. The method of one of examples 1 to 6, where the filling of the first hole with the metal includes overfilling the first hole with the metal and covering at least part of the first dielectric layer with the metal.
Example 8. The method of one of examples 1 to 7, further including polishing and planarizing a metal top surface of the metal and a first-dielectric-layer top surface of the first dielectric layer.
Example 9. The method of one of examples 1 to 8, where the first hole is a via hole, and where the method further includes forming a metal via portion of an interconnect structure in the via hole.
Example 10. The method of one of examples 1 to 9, where the first hole is a via hole, where the first oxide liner covers a first-dielectric-layer top surface of the first dielectric layer, where the method further includes forming an interconnect structure using a subtractive semi-damascene process, and where the subtractive semi-damascene process includes: overfilling the via hole with the metal to form a metal via portion of the interconnect structure, and such that a first thickness of the metal is formed on a first-oxide-liner top surface of the first oxide liner over the first dielectric layer, where the first-oxide-liner top surface is above the via hole, and where a metal top surface of the metal is separated from the first-oxide-liner top surface by the first thickness; forming and patterning a mask on the metal top surface of the metal; etching the metal to expose a first-exposed-oxide-liner part of the first oxide liner at the first-oxide-liner top surface using the mask to pattern the metal forming a metal line portion of the interconnect structure from the metal, where the metal line portion is contiguous with the metal via portion of the interconnect structure; using the first-exposed-oxide-liner part of the first oxide liner to protect the first dielectric layer during the etching of the metal; depositing a second dielectric layer over the first dielectric layer and the metal line portion of the interconnect structure; and planarizing a second-dielectric-layer top surface of the second dielectric layer and a metal-line-portion top surface of the metal line portion.
Example 11. The method of one of examples 1 to 10, where the metal includes at least one member from a group consisting of ruthenium, niobium, and molybdenum.
Example 12. The method of one of examples 1 to 11, where the oxide material of the first oxide liner has a second dielectric constant of 3.9 or greater than 3.9.
Example 13. A method for making a semiconductor device, the method including: providing a first intermediate structure in a first plasma chamber, where the first intermediate structure includes a first dielectric layer, where the first dielectric layer includes a low-k dielectric material having a first dielectric constant less than 3.9, where the first intermediate structure further includes an underlying conductive structure below the first dielectric layer; etching the first dielectric layer to form a first hole therein using a first set of plasma chamber parameters in the first plasma chamber, where the etching of the first dielectric layer to form the first hole opens to the underlying conductive structure and exposes an underlying-conductive-structure top surface of the underlying conductive structure; depositing a first oxide liner over the first intermediate structure and on sidewalls of the first hole in the first plasma chamber using a first direct current superposition process with a second set of plasma chamber parameters, where the second set of plasma chamber parameters differs from the first set of plasma chamber parameters; removing a hole-bottom portion of the first oxide liner at a bottom of the first hole using a third set of plasma chamber parameters in the first plasma chamber, such that at least part of the first oxide liner remains on at least part of the sidewalls of the first hole, where the third set of plasma chamber parameters differs from the first set of plasma chamber parameters and the second set of plasma chamber parameters, where the removing of the hole-bottom portion of the first oxide liner opens to the underlying conductive structure and exposes the underlying-conductive-structure top surface of the underlying conductive structure; and filling the first hole with a metal such that the metal is directly on the underlying-conductive-structure top surface of the underlying conductive structure at the bottom of the first hole, such that the metal is directly on the first oxide liner, and such that the first oxide liner is between the metal and the first dielectric layer at least at the sidewalls of the first hole.
Example 14. The method of example 13, where the metal includes at least one member from a group consisting of ruthenium, niobium, and molybdenum.
Example 15. The method of one of examples 13 or 14, where the first oxide liner includes an oxide material having a second dielectric constant of 3.9 or greater than 3.9.
Example 16. The method of one of examples 13 to 15, where the first hole includes a first trench and a first via hole, where the first trench is contiguous with the first via hole, where the depositing of the first oxide liner includes depositing the first oxide liner on a first sidewall of the sidewalls at the first via hole and depositing the first oxide liner on a second sidewall of the sidewalls at the first trench, and where the filling of the first hole with the metal includes filling the first via hole with the metal and filling the first trench with the metal.
Example 17. The method of one of examples 13 to 16, where the depositing of the first oxide liner includes a plasma enhanced physical deposition of the first oxide liner.
Example 18. The method of one of examples 13 to 17, where the depositing of the first oxide liner is conformal to the first intermediate structure and the first hole.
Example 19. The method of one of examples 13 to 18, where the removing a hole-bottom portion of the first oxide liner at the bottom of the first hole using the third set of plasma chamber parameters in the first plasma chamber includes a second direct current superposition process.
Example 20. A method for making a semiconductor device, the method including: providing a first intermediate structure in a first plasma chamber, where the first intermediate structure includes a first dielectric layer, where the first dielectric layer includes a low-k dielectric material including silicon and oxygen, where the low-k dielectric material has a first dielectric constant less than 3.9; etching the first dielectric layer to form a first hole therein using a first set of plasma chamber parameters in the first plasma chamber; depositing a first oxide liner over the first intermediate structure and directly on sidewalls of the first hole in the first plasma chamber using a direct current superposition process with a second set of plasma chamber parameters, where the first oxide liner includes a silicon dioxide material having a second dielectric constant of 3.9 or greater than 3.9, where the second set of plasma chamber parameters differs from the first set of plasma chamber parameters; removing a hole-bottom portion of the first oxide liner at a bottom of the first hole using a third set of plasma chamber parameters in the first plasma chamber, such that at least part of the first oxide liner remains on at least part of the sidewalls of the first hole, where the third set of plasma chamber parameters differs from the first set of plasma chamber parameters and the second set of plasma chamber parameters; and filling the first hole with ruthenium such that the ruthenium is directly on the first oxide liner and such that the first oxide liner is between the ruthenium and the first dielectric layer at least at the sidewalls of the first hole.
Example 21. A semiconductor device including: a first dielectric layer having a first hole therein, where the first dielectric layer includes a low-k dielectric material having a first dielectric constant less than 3.9; a first oxide liner directly on the first dielectric layer at a sidewall of the first hole, where the first oxide liner includes an oxide material having a second dielectric constant of 3.9 or greater than 3.9; and a ruthenium conductive structure directly on the first oxide liner in the first hole.
Example 22. The semiconductor device of example 21, where the first hole includes a via hole, and where the ruthenium conductive structure is a ruthenium plug.
Example 23. The semiconductor device of one of examples 21 or 22, where the first oxide liner includes silicon dioxide.
Example 24. The semiconductor device of one of examples 21 to 23, where the first hole includes a trench and a via hole, where the trench is contiguous with the via hole, where the ruthenium conductive structure includes a ruthenium plug and a ruthenium line, where the ruthenium line is contiguous with the ruthenium plug, where the ruthenium plug is in the via hole, and where the ruthenium line is in the trench.
Example 25. The semiconductor device of one of examples 21 to 24, where the low-k dielectric material includes one of or any combination of silicon oxycarbide (SiOC), silicon oxycarbonitride (SiOCN), fluorinated silicon dioxide (FSG), organosilicate glass (OSG), silicon-carbon-oxygen-hydrogen (SiCOH), porous SiCOH, hydrogen silsesquioxane (HSQ), Methylsilsesquioxane (MSQ), nanoporous silicon dioxide, organic polymer having the first dielectric constant less than 2.6, silica-based aerogel having the first dielectric constant less than 2.4, spin-on organic material having the first dielectric constant less than 2.6, benzocyclobutene (BCB), or organosilicate material having the first dielectric constant less than 2.7.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for making a semiconductor device, the method comprising:
providing a first intermediate structure in a first plasma chamber, wherein the first intermediate structure comprises a first dielectric layer, wherein the first dielectric layer comprises a low-k dielectric material having a first dielectric constant less than 3.9;
etching the first dielectric layer to form a first hole therein in the first plasma chamber;
forming a first oxide liner on sidewalls of the first hole using at least one direct current superposition process in the first plasma chamber, such that at least part of a bottom of the first hole is not covered by the first oxide liner, wherein the first oxide liner comprises an oxide material that differs from the low-k dielectric material of the first dielectric layer; and
filling the first hole with a metal such that the metal is on the first oxide liner and such that the first oxide liner is between the metal and the first dielectric layer at least at the sidewalls of the first hole.

2. The method of claim 1, wherein the first intermediate structure further comprises an underlying conductive structure below the first dielectric layer,
wherein the etching of the first dielectric layer to form the first hole opens to the underlying conductive structure and exposes an underlying-conductive-structure top surface of the underlying conductive structure,
wherein the forming of the first oxide liner opens to the underlying conductive structure and exposes the underlying-conductive-structure top surface of the underlying conductive structure, and
wherein the filling of the first hole with the metal comprises depositing the metal directly on the underlying-conductive-structure top surface of the underlying conductive structure at the bottom of the first hole.

3. The method of claim 1, wherein the etching of the first dielectric layer to form the first hole therein is performed using a first set of plasma-chamber parameters in the first plasma chamber; and
wherein the forming of the first oxide liner comprises:
depositing the first oxide liner over the first intermediate structure and on the sidewalls of the first hole in the first plasma chamber using a first direct current superposition process with a second set of plasma-chamber parameters, wherein the second set of plasma-chamber parameters differs from the first set of plasma-chamber parameters, and
removing a hole-bottom portion of the first oxide liner at the bottom of the first hole using a third set of plasma-chamber parameters in the first plasma chamber, such that at least part of the first oxide liner remains on at least part of the sidewalls of the first hole, wherein the third set of plasma-chamber parameters differs from the first set of plasma-chamber parameters and the second set of plasma-chamber parameters.

4. The method of claim 3, wherein the first intermediate structure further comprises an underlying conductive structure below the first dielectric layer,
wherein the etching of the first dielectric layer to form the first hole opens to the underlying conductive structure and exposes an underlying-conductive-structure top surface of the underlying conductive structure,
wherein the removing of the hole-bottom portion of the first oxide liner opens to the underlying conductive structure and exposes the underlying-conductive-structure top surface of the underlying conductive structure, and
wherein the filling of the first hole with the metal comprises depositing the metal directly on the underlying-conductive-structure top surface of the underlying conductive structure at the bottom of the first hole.

5. The method of claim 1, wherein the first hole includes a first trench and a first via hole, wherein the first trench is contiguous with the first via hole,
wherein the forming of the first oxide liner comprises forming the first oxide liner on a first sidewall of the sidewalls at the first via hole and forming the first oxide liner on a second sidewall of the sidewalls at the first trench, and
wherein the filling of the first hole with the metal comprises filling the first via hole with the metal and filling the first trench with the metal.

6. The method of claim 5, wherein at least part of the metal is formed directly on the first dielectric layer at a first-trench-bottom portion of the first trench.

7. The method of claim 1, wherein the filling of the first hole with the metal comprises overfilling the first hole with the metal and covering at least part of the first dielectric layer with the metal.

8. The method of claim 7, further comprising polishing and planarizing a metal top surface of the metal and a first-dielectric-layer top surface of the first dielectric layer.

9. The method of claim 1, wherein the first hole is a via hole, and wherein the method further comprises forming a metal via portion of an interconnect structure in the via hole.

10. The method of claim 1, wherein the first hole is a via hole, wherein the first oxide liner covers a first-dielectric-layer top surface of the first dielectric layer, wherein the method further comprises forming an interconnect structure using a subtractive semi-damascene process, and wherein the subtractive semi-damascene process comprises:
overfilling the via hole with the metal to form a metal via portion of the interconnect structure, and such that a first thickness of the metal is formed on a first-oxide-liner top surface of the first oxide liner over the first dielectric layer, wherein the first-oxide-liner top surface is above the via hole, and wherein a metal top surface of the metal is separated from the first-oxide-liner top surface by the first thickness;
forming and patterning a mask on the metal top surface of the metal;
etching the metal to expose a first-exposed-oxide-liner part of the first oxide liner at the first-oxide-liner top surface using the mask to pattern the metal forming a metal line portion of the interconnect structure from the metal, wherein the metal line portion is contiguous with the metal via portion of the interconnect structure;
using the first-exposed-oxide-liner part of the first oxide liner to protect the first dielectric layer during the etching of the metal;
depositing a second dielectric layer over the first dielectric layer and the metal line portion of the interconnect structure; and
planarizing a second-dielectric-layer top surface of the second dielectric layer and a metal-line-portion top surface of the metal line portion.

11. The method of claim 1, wherein the metal comprises at least one member from a group consisting of ruthenium, niobium, and molybdenum.

12. The method of claim 1, wherein the oxide material of the first oxide liner has a second dielectric constant of 3.9 or greater than 3.9.

13. A method for making a semiconductor device, the method comprising:
providing a first intermediate structure in a first plasma chamber, wherein the first intermediate structure comprises a first dielectric layer, wherein the first dielectric layer comprises a low-k dielectric material having a first dielectric constant less than 3.9, wherein the first intermediate structure further comprises an underlying conductive structure below the first dielectric layer;
etching the first dielectric layer to form a first hole therein using a first set of plasma-chamber parameters in the first plasma chamber, wherein the etching of the first dielectric layer to form the first hole opens to the underlying conductive structure and exposes an underlying-conductive-structure top surface of the underlying conductive structure;
depositing a first oxide liner over the first intermediate structure and on sidewalls of the first hole in the first plasma chamber using a first direct current superposition process with a second set of plasma-chamber parameters, wherein the second set of plasma-chamber parameters differs from the first set of plasma-chamber parameters;
removing a hole-bottom portion of the first oxide liner at a bottom of the first hole using a third set of plasma-chamber parameters in the first plasma chamber, such that at least part of the first oxide liner remains on at least part of the sidewalls of the first hole, wherein the third set of plasma-chamber parameters differs from the first set of plasma-chamber parameters and the second set of plasma-chamber parameters, wherein the removing of the hole-bottom portion of the first oxide liner opens to the underlying conductive structure and exposes the underlying-conductive-structure top surface of the underlying conductive structure; and
filling the first hole with a metal such that the metal is directly on the underlying-conductive-structure top surface of the underlying conductive structure at the bottom of the first hole, such that the metal is directly on the first oxide liner, and such that the first oxide liner is between the metal and the first dielectric layer at least at the sidewalls of the first hole.

14. The method of claim 13, wherein the metal comprises at least one member from a group consisting of ruthenium, niobium, and molybdenum.

15. The method of claim 13, wherein the first oxide liner comprises an oxide material having a second dielectric constant of 3.9 or greater than 3.9.

16. The method of claim 13, wherein the first hole includes a first trench and a first via hole, wherein the first trench is contiguous with the first via hole,
wherein the depositing of the first oxide liner comprises depositing the first oxide liner on a first sidewall of the sidewalls at the first via hole and depositing the first oxide liner on a second sidewall of the sidewalls at the first trench, and
wherein the filling of the first hole with the metal comprises filling the first via hole with the metal and filling the first trench with the metal.

17. The method of claim 13, wherein the depositing of the first oxide liner includes a plasma-enhanced physical deposition of the first oxide liner.

18. The method of claim 13, wherein the depositing of the first oxide liner is conformal to the first intermediate structure and the first hole.

19. The method of claim 13, wherein the removing a hole-bottom portion of the first oxide liner at the bottom of the first hole using the third set of plasma-chamber parameters in the first plasma chamber comprises a second direct current superposition process.

20. A method for making a semiconductor device, the method comprising:
providing a first intermediate structure in a first plasma chamber, wherein the first intermediate structure comprises a first dielectric layer, wherein the first dielectric layer comprises a low-k dielectric material including silicon and oxygen, wherein the low-k dielectric material has a first dielectric constant less than 3.9;
etching the first dielectric layer to form a first hole therein using a first set of plasma-chamber parameters in the first plasma chamber;
depositing a first oxide liner over the first intermediate structure and directly on sidewalls of the first hole in the first plasma chamber using a direct current superposition process with a second set of plasma-chamber parameters, wherein the first oxide liner comprises a silicon dioxide material having a second dielectric constant of 3.9 or greater than 3.9, wherein the second set of plasma-chamber parameters differs from the first set of plasma-chamber parameters;
removing a hole-bottom portion of the first oxide liner at a bottom of the first hole using a third set of plasma-chamber parameters in the first plasma chamber, such that at least part of the first oxide liner remains on at least part of the sidewalls of the first hole, wherein the third set of plasma-chamber parameters differs from the first set of plasma-chamber parameters and the second set of plasma-chamber parameters; and
filling the first hole with ruthenium such that the ruthenium is directly on the first oxide liner and such that the first oxide liner is between the ruthenium and the first dielectric layer at least at the sidewalls of the first hole.
